(19) United States
(12) Patent Application Publication
(10) Pub. No.: US 2025/0239973 A1
(43) Pub. Date: Jul. 24, 2025

(54) TRACKER CIRCUIT AND TRACKING METHOD

(71) Applicant: Murata Manufacturing Co., Ltd., Nagaokakyo-shi (JP)

(72) Inventors: John HOVERSTEN, Waltham, MA (US); David J. PERREAULT, Waltham, MA (US); Muneharu KATO, Nagaokakyo-shi (JP)

(21) Appl. No.: 19/071,287

(22) Filed: Mar. 5, 2025

Related U.S. Application Data
(63) Continuation of application No. PCT/JP2023/033562, filed on Sep. 14, 2023.
(60) Provisional application No. 63/408,974, filed on Sep. 22, 2022.

(51) Int. Cl. H03F 1/02; H03F 3/24; H03F 3/72

(52) U.S. Cl. CPC H03F 1/0227; H03F 3/245; H03F 3/72; H03F 2200/102; H03F 2200/105; H03F 2200/451; H03F 2203/7209

(57) ABSTRACT

Some exemplary aspects of the disclosure provide a tracker circuit that includes an output switching circuit, a first voltage supply path and a filter circuit. The output switching circuit is configured to selectively output at least one of a plurality of discrete voltages. The first voltage supply path is configured to connect the output switching circuit and a first power amplifier to provide the at least one of the plurality of discrete voltages to the first power amplifier. The filter circuit is configured to be connected in shunt with the first voltage supply path, the first power amplifier is configured to amplify a first radio frequency signal of a first band with time division duplex being applied.

### CROSS REFERENCE TO RELATED APPLICATIONS

This application is a continuation of International Application No. PCT/JP2023/033562, filed Sep. 14, 2023, which claims priority to U.S. Patent Provisional Application No. 63/408,974, filed Sep. 22, 2022, the entire contents of each of which are hereby incorporated by reference.

### TECHNICAL FIELD

The present disclosure relates to a tracker circuit and a tracking method.

### BACKGROUND

An envelope tracking (ET) mode has been used in recent years for power amplifiers to improve power-added efficiency (PAE). An example circuit, such as described in U.S. Pat. No. 8,829,993, uses a technique related to a digital ET mode that supplies a plurality of discrete voltages. Another example circuit, such as described in U.S. Pat. No. 10,686,407, uses a technique related to a symbol power tracking (SPT) mode that supplies a plurality of discrete voltages.

### SUMMARY

The techniques according to the example circuits mentioned above, however, may result in increased distortion of a radio frequency signal in power amplifiers.

Accordingly, the exemplary aspects of the present disclosure provide a tracker circuit and a tracking method that is configured for reduced distortion of a radio frequency signal amplified by using a plurality of discrete voltages.

Some exemplary aspects of the disclosure provide a tracker circuit that includes an output switching circuit, a first voltage supply path and a filter circuit. The output switching circuit is configured to selectively output at least one of a plurality of discrete voltages. The first voltage supply path is configured to connect the output switching circuit and a first power amplifier to provide the at least one of the plurality of discrete voltages to the first power amplifier. The filter circuit is configured to be connected in shunt with the first voltage supply path, the first power amplifier is configured to amplify a first radio frequency signal of a first band with time division duplex being applied.

Some exemplary aspects of the disclosure provide a tracker circuit that includes a first external connection terminal, an output switching circuit, a first voltage supply path and filter circuit. The first external connection terminal is configured to be connected to a first power amplifier, the first power amplifier is configured to amplify a first radio frequency signal of a first band with time division duplex being applied. The output switching circuit configured to selectively output at least one of a plurality of discrete voltages to the first external connection terminal. The first voltage supply path is configured to connect the output switching circuit to the first external connection terminal. The filter circuit is configured to be connected between the first voltage supply path and a ground.

Some exemplary aspects of the disclosure provide a tracking method. The tracking method includes when a radio frequency signal with time division duplex being applied has a channel bandwidth greater than or equal to a threshold bandwidth, disconnecting a filter circuit to a voltage supply path of a power amplifier to be used to amplify the radio frequence signal; when the channel bandwidth is less than the threshold bandwidth, connecting the filter circuit to the voltage supply path; and selectively supplying at least one of a plurality of discrete voltages to the power amplifier via the voltage supply path.

In another exemplary aspect, a tracker circuit is provided that includes an output switching circuit, a first voltage supply path, and a filter circuit. The output switching circuit is configured to selectively output at least one of a plurality of discrete voltages to a first power amplifier. The first voltage supply path connects the output switching circuit and the first power amplifier. The filter circuit is connected to the first voltage supply path. The first power amplifier is configured to amplify a first radio frequency signal of a first band to which time division duplex is applied. The filter circuit is connected not in series but in shunt with the first voltage supply path.

In yet another exemplary aspect, a tracker circuit is provided that includes a first external connection terminal, an output switching circuit, a first voltage supply path, and a filter circuit. The first external connection terminal is connected to a first power amplifier. The first power amplifier is configured to amplify a first radio frequency signal of a first band to which time division duplex is applied. The output switching circuit is configured to selectively output at least one of a plurality of discrete voltages to the first external connection terminal. The first voltage supply path connects the output switching circuit directly to the first external connection terminal. The filter circuit is connected between the first voltage supply path and ground.

In yet another exemplary aspect, a tracking method is provided that includes: when a radio frequency signal that is to be amplified by a power amplifier and that is in a band to which time division duplex is applied has a channel bandwidth greater than or equal to a threshold bandwidth, not connecting a filter circuit to a voltage supply path; when the channel bandwidth is less than the threshold bandwidth, connecting the filter circuit to the voltage supply path; and selectively supplying at least one of a plurality of discrete voltages to the power amplifier via the voltage supply path.

A tracker circuit and other techniques according to an exemplary aspect of the present disclosure provide for reduced distortion of a radio frequency signal amplified by using a plurality of discrete voltages.

### BRIEF DESCRIPTION OF DRAWINGS

FIG. 1A is a graph illustrating an example of the progression of power supply voltage in an average power tracking (APT) mode.

FIG. 1B is a graph illustrating an example of the progression of power supply voltage in an analog ET mode.

FIG. 1C is a graph illustrating an example of the progression of power supply voltage in a digital ET mode.

FIG. 2 is a circuit diagram of a communication device according to Exemplary Embodiment 1.

FIG. 3 is a circuit diagram of a pre-regulator circuit, a switched-capacitor circuit, an output switching circuit, and a filter circuit according to Exemplary Embodiment 1.

FIG. 4 is a circuit diagram of a digital control circuit according to Exemplary Embodiment 1.

FIG. 5 is a flowchart illustrating a tracking method according to Exemplary Embodiment 1.

FIG. 6 is a plan view of a tracker module according to Exemplary Embodiment 1.

FIG. 7 is a plan view of the tracker module according to Exemplary Embodiment 1.

FIG. 8 is a cross-sectional view of the tracker module according to Exemplary Embodiment 1.

FIG. 9 is a circuit diagram of a communication device according to Exemplary Embodiment 2.

FIG. 10 is a circuit diagram of a filter circuit according to Exemplary Embodiment 2.

FIG. 11 is a circuit diagram of a filter circuit according to a modification of Exemplary Embodiment 2.

FIG. 12 is a circuit diagram of a communication device according to Exemplary Embodiment 3.

FIG. 13 is a circuit diagram of a filter circuit according to Exemplary Embodiment 3.

FIG. 14 is a circuit diagram of a filter circuit according to another exemplary embodiment.

### DETAILED DESCRIPTION OF EXEMPLARY EMBODIMENTS

In general, when a power amplifier receives supply of a plurality of discrete voltages, noise increases due to discrete changes in voltage level. The increase in noise is particularly pronounced when a mode such as a digital ET mode is used, which is a mode involving rapid discrete changes in voltage level.

Moreover, when a radio frequency signal to be amplified by a power amplifier is a transmission signal of a frequency division duplex (FDD) band, a filter for attenuating the noise of the difference frequency between a transmission channel frequency and a reception channel frequency is inserted into a voltage supply path in order to prevent the intermodulation distortion (IMD) between noise and the transmission signal (e.g., distortion components resulting from the addition of the frequency of the noise to the frequency of the transmission signal) from interfering with a reception signal. If a radio frequency signal to be amplified by the power amplifier is a transmission signal of a time division duplex (TDD) band, transmission and reception are switched therebetween in a time-divided manner, and thus IMD does not interfere with a reception signal. This means that if a transmission signal of the TDD band is to be amplified, a filter need not necessarily be inserted into the voltage supply path.

However, the inventors have found the following issue: even in the case of the TDD band, when the power supply voltage has large noise, spurious emissions increase due to IMD, leading to degradation of an adjacent channel power ratio/adjacent channel leakage ratio (ACPR/ACLR).

Accordingly, a detailed description will be given below, based on exemplary embodiments, of a tracker circuit and a tracking method that allow for reduced distortion of a radio frequency signal in a case where a plurality of discrete voltages are to be supplied to a power amplifier configured to amplify a transmission signal of the TDD band. Exemplary embodiments described below each represent generic or specific examples. Features presented in the following exemplary embodiments, such as numerical values, shapes, materials, constituent elements, and the positioning and connection of constituent elements, are illustrative only and not intended to be limiting of the exemplary aspects of the present disclosure.

The drawings are schematic in nature with emphases, omissions, or proportion adjustments provided to illustrate the present disclosure, and do not necessarily represent exact details. Accordingly, the illustrated shapes, positional relationships, and proportions may differ from the actuality. Throughout the drawings, identical reference signs are used to designate substantially identical features, and repetitive description will be sometimes omitted or simplified.

In the figures described below and for purposes of the disclosure, the x-axis and the y-axis are orthogonal to each other in a plane parallel to a major face of a module laminate. In an exemplary aspect, if the module laminate has a rectangular shape in plan view, the x-axis is parallel to a first side of the module laminate, and the y-axis is parallel to a second side orthogonal to the first side of the module laminate. A z-axis is an axis perpendicular to the major face of the module laminate. The z-axis has a positive direction defined as an upward direction, and a negative direction defined as a downward direction.

As used in the following description of circuit configurations according to the present disclosure, expressions such as “connected” can refer to not only that circuit elements are directly connected by a connection terminal and/or a wiring conductor, but also that circuit elements are electrically connected with another circuit element interposed therebetween. Expressions such as “directly connected” can refer to that circuit elements are directly connected by a connection terminal and/or a wiring conductor with no other circuit element interposed therebetween. Expressions such as “connected between A and B” can refer to being positioned between A and B and connected to both A and B, and can refer to being connected in series with a path located between A and B. Expressions such as “path located between A and B” can refer to a path formed by a conductor that electrically connects A to B. Expressions such as “connected in series with a path” can refer to being connected in series with the path, and can refer to being connected between one end of the path and the other end of the path. Expressions such as “connected in shunt with a path” can refer to being connected between the path and ground.

As used herein with regard to the positioning of components according to the exemplary aspects of the present disclosure, expressions such as “a component is disposed at a substrate” include that the component is disposed on a major face of the substrate, and that the component is disposed in the substrate. Expressions such as “a component is disposed on a major face of a substrate” include not only that the component is disposed in contact with the major face of the substrate, but also that the component is disposed above the major face without making contact with the major face (e.g., the component is stacked on another component disposed in contact with the major face). The expressions such as “a component is disposed on a major face of a substrate” may also include that the component is disposed in a recess defined in the major face. Expressions such as “a component is disposed in a substrate” include, in addition to the meaning that the component is encapsulated in the module laminate, the following meanings: the entirety of the component is disposed between opposite major faces of the substrate but part of the component is not covered by the substrate; and only part of the component is disposed in the substrate.

As used herein with regard to the positioning of components according to the exemplary aspects of the present disclosure, expressions such as “plan view of a module laminate” can refer to an object that is orthogonally projected onto an xy-plane and viewed from the positive side of the z-axis. Expressions such as “A overlaps B in plan view” can refer to that at least part of the region of A orthogonally projected onto the xy-plane overlaps at least part of the region of B orthogonally projected onto the xy-plane. Expressions such as “A is disposed between B and C” can refer to that at least one of line segments each connecting a given point in B and a given point in C passes through A.

As used herein with regard to the positioning of components according to the exemplary aspects of the present disclosure, expression such as “A is disposed adjacent to B” indicate that A and B are disposed in proximity to each other. In an exemplary aspect, such expressions can refer to that no other circuit component exists in a space where A faces B. In other words, the expressions such as “A is disposed adjacent to B” can refer to that none of a plurality of line segments each extending from a given point on a surface of A facing B to B in the direction normal to the surface passes through a circuit component other than A and B. In this regard, a circuit component can refer to a component including an active element and/or a passive element. That is, examples of such circuit components include active components such as transistors or diodes, and passive components such as inductors, transformers, capacitors, or resistors, but do not include electromechanical components such as terminals, connectors, or wiring lines.

As used in the present disclosure, expressions such as “terminal” can refer to a point where a conductor within an element terminates. If the impedance of a conductor located between elements is sufficiently low, a terminal is interpreted not only as a single point, but also as any given point on the conductor located between the elements or as the entire conductor.

Further, “parallel”, “perpendicular”, or other such expressions indicative of the relationship between elements, and “rectangular” or other such expressions indicative of a shape of an element, as well as numerical ranges are not intended to represent only their strict meanings but are also include their substantial equivalents, for example, equivalents with deviations or differences of about several percent.

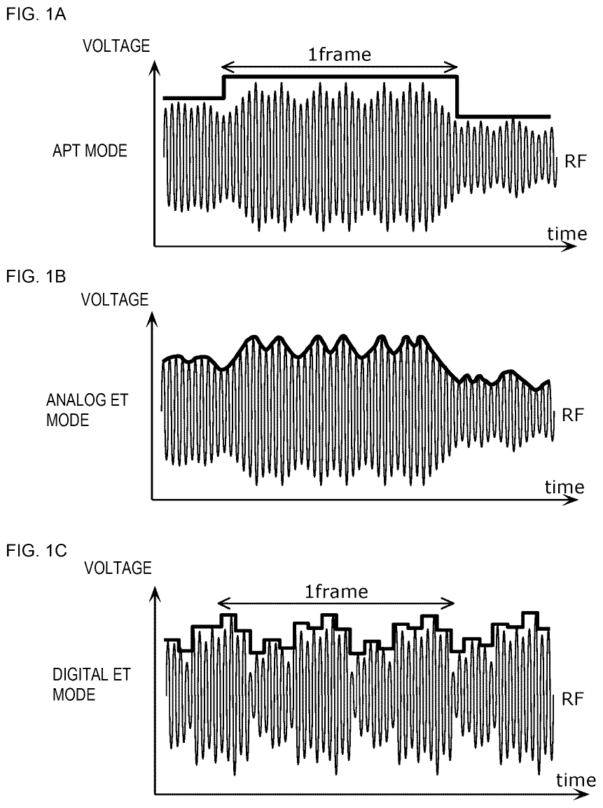

First, as a technique for efficiently amplifying a radio frequency signal, a tracking mode is described below in which a power amplifier receives a power supply voltage that is dynamically adjusted with the passage of time based on the radio frequency signal. A tracking mode refers to a mode that dynamically adjusts the power supply voltage to be applied to a power amplifier. Several types of tracking modes exist, of which APT and ET modes (including an analog ET mode and a digital ET mode) will now be described with reference to FIGS. 1A to 1C. In FIGS. 1A to 1C, the horizontal axis represents time, and the vertical axis represents voltage. A thick solid line represents power supply voltage, and a thin solid line (waveform) represents modulated signal.

FIG. 1A is a graph illustrating an example of the progression of power supply voltage in the APT mode. In the APT mode, the power supply voltage is varied across a plurality of discrete voltage levels in units of one frame based on average power.

For purposes of this disclosure, a frame can refer to a unit forming a radio frequency signal (e.g., a modulated signal). For example, in 5th Generation New Radio (5GNR) and Long Term Evolution (LTE), a frame includes ten subframes. Each subframe includes a plurality of slots. Each slot includes a plurality of symbols. A subframe has a length of 1 ms, and a frame has a length of 10 ms.

A mode in which the voltage level is varied in units of one frame or in larger units based on average power is referred to as APT mode, which is distinguished from a mode in which the voltage level is varied in units smaller than one frame (e.g., in units of subframes, slots, or symbols). For example, a mode in which the voltage level is varied in units of symbols is referred to as symbol power tracking (SPT) mode, which is distinguished from the APT mode.

FIG. 1B is a graph illustrating an example of the progression of power supply voltage in the analog ET mode. In the analog ET mode, the power supply voltage is varied continuously based on an envelope signal to thereby track the envelope of a modulated signal.

An envelope signal is a signal representing the envelope of a modulated signal. An envelope value is expressed as, for example, the square root of (I²+Q²). In this case, (I, Q) represents a constellation point. A constellation point is a point representing, on a constellation diagram, a signal modulated by digital modulation. (I, Q) is determined by, for example, a baseband integrated circuit (BBIC) based on, for example, transmission information.

FIG. 1C is a graph illustrating an example of the progression of power supply voltage in the digital ET mode. In the digital ET mode, the power supply voltage is varied across a plurality of discrete voltage levels within one frame based on an envelope signal to thereby track the envelope of a modulated signal.

### Exemplary Embodiment 1

The Exemplary Embodiment 1 will now be described. A communication device 7A according to the Exemplary Embodiment 1 corresponds to user equipment (UE) in a cellular network. Typical examples of the communication device 7A include a mobile phone, a smartphone, a tablet computer, and a wearable device. The communication device 7A may be an Internet of Things (IoT) sensor device, a medical/healthcare device, a vehicle, an unmanned aerial vehicle (UAV) (a so-called drone), or an automated guided vehicle (AGV). The communication device 7A may also function as a base station (BS) in a cellular network.

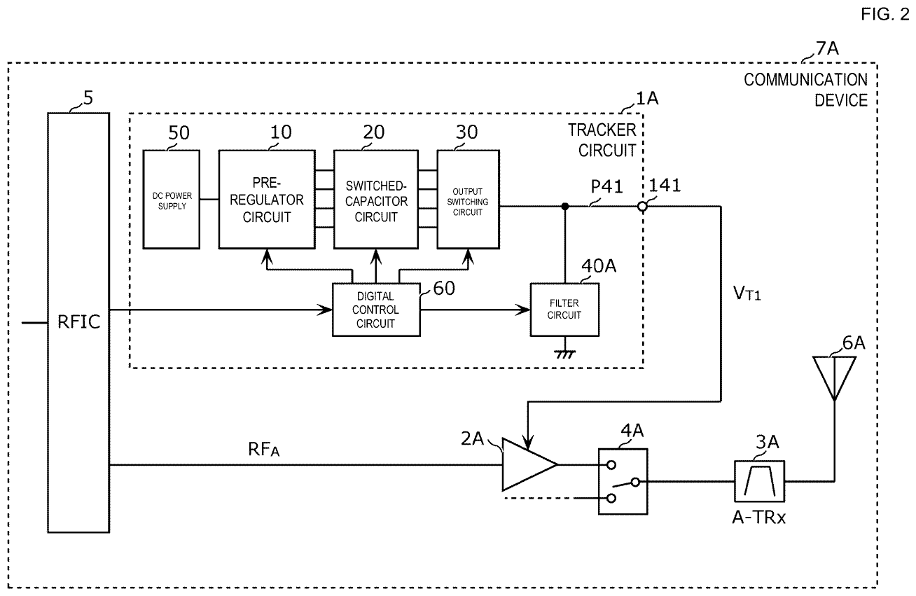

The circuit configuration of each of the communication device 7A and a tracker circuit 1A according to the Exemplary Embodiment 1 will now be described with reference to FIG. 2. FIG. 2 is a circuit diagram of the communication device 7A according to the Exemplary Embodiment 1.

FIG. 2 illustrates an exemplary circuit configuration. The communication device 7A and the tracker circuit 1A may be implemented by using any one of a wide variety of circuit implementations and circuit technologies. Therefore, the description of the communication device 7A and the tracker circuit 1A provided below is not to be construed restrictively.

### 1.1 Circuit Configuration of Communication Device 7A

First, the communication device 7A according to the Exemplary Embodiment 1 will be described with reference to FIG. 2. The communication device 7A includes the tracker circuit 1A, a power amplifier 2A, a filter 3A, a switch 4A, a radio frequency integrated circuit (RFIC) 5, and an antenna 6A.

The tracker circuit 1A is configured to supply a plurality of discrete voltages V_{T1} based on a tracking mode to the power amplifier 2A. The tracking mode used may be, but is not limited to, the digital ET mode or the SPT mode.

As illustrated in FIG. 2, the tracker circuit 1A includes a pre-regulator circuit 10, a switched-capacitor circuit 20, an output switching circuit 30, a filter circuit 40A, a direct current (DC) power supply 50, a digital control circuit 60, and an external connection terminal 141.

The external connection terminal 141 is an example of a first external connection terminal. The external connection terminal 141 is connected at a location outside the tracker circuit 1A to the power amplifier 2A, and connected at a location inside the tracker circuit 1A to the output switching circuit 30 via a voltage supply path P41.

The voltage supply path P41 is an example of a first voltage supply path. The voltage supply path P41 is part of a path connecting the output switching circuit 30 and the power amplifier 2A. In this case, the voltage supply path P41 is a path directly connecting the output switching circuit 30 and the external connection terminal 141. That is, no circuit element (e.g., an active element and a passive element) is connected in series with the voltage supply path P41.

The pre-regulator circuit 10 includes a power inductor, and a switch. A power inductor is an inductor used to step up and/or step down a DC voltage. The power inductor is connected in series with a DC path. The power inductor may be connected (e.g., disposed in parallel) between the DC path and ground. The pre-regulator circuit 10 is configured to convert an input voltage into a first voltage by using the power inductor. Such a pre-regulator circuit 10 may be referred to also as magnetic regulator or DC-DC converter.

The switched-capacitor circuit 20 includes a plurality of capacitors, and a plurality of switches. The switched-capacitor circuit 20 is configured to receive the first voltage from the pre-regulator circuit 10, and generating, from the first voltage, a plurality of second voltages as a plurality of discrete voltages each having a corresponding one of a plurality of discrete voltage levels. The switched-capacitor circuit 20 may be referred to also as switched-capacitor voltage ladder.

The output switching circuit 30 is configured to select at least one voltage from among the second voltages generated by the switched-capacitor circuit 20, and output the selected voltage to the power amplifier 2A to thereby modulate the power supply voltage. At this time, the voltage is supplied to the power amplifier 2A via the voltage supply path P41. The output switching circuit 30 is controlled based on a digital control signal. The output switching circuit 30 may be referred to also as supply modulator circuit.

The filter circuit 40A is a pulse shaping network. The filter circuit 40A is configured to be connectable in shunt with the voltage supply path P41. The filter circuit 40A is configured to attenuate noise components from signals (e.g., a plurality of discrete voltages) transmitted through the voltage supply path P41.

The DC power supply 50 is configured to supply a DC voltage to the pre-regulator circuit 10. A suitable non-limiting example of the DC power supply 50 is a rechargeable battery.

The digital control circuit 60 is configured to control the following components based on a digital control signal provided from the RFIC 5: the pre-regulator circuit 10, the switched-capacitor circuit 20, the output switching circuit 30, and the filter circuit 40A.

The tracker circuit 1A may be configured not to include at least one of the following components: the pre-regulator circuit 10, the switched-capacitor circuit 20, the output switching circuit 30, the filter circuit 40A, the DC power supply 50, and the digital control circuit 60. In one example, the tracker circuit 1A may be configured not to include the DC power supply 50. In another example, any combination of the pre-regulator circuit 10, the switched-capacitor circuit 20, the output switching circuit 30, and the filter circuit 40A may be integrated into a single circuit. In another example, the tracker circuit 1A may include a plurality of voltage supply circuits as with the configuration described in Patent Document 2, instead of the pre-regulator circuit 10 and the switched-capacitor circuit 20. In this case, the output switching circuit 30 may be configured to select at least one of the voltage supply circuits.

The power amplifier 2A is an example of a first power amplifier. The power amplifier 2A is connected between the RFIC 5 and the filter 3A. Further, the power amplifier 2A is connected to the tracker circuit 1A. The power amplifier 2A is configured to amplify, by using the discrete voltages V_{T1} received from the tracker circuit 1A, a radio frequency signal RF_{A}(an example of a first radio frequency signal) of Band A received from the RFIC 5.

The filter 3A is connected between the power amplifier 2A and the antenna 6A. The filter 3A is a band pass filter with a passband that includes Band A.

Band A is a frequency band for communication systems built by using radio access technology (RAT). Band A is predefined by standardizing bodies or other entities (e.g., 3rd Generation Partnership Project (3GPP)® and Institute of Electrical and Electronics Engineers (IEEE)). Examples of such communication systems include 5th Generation New Radio (5GNR) systems, Long Term Evolution (LTE) systems, and Wireless Local Area Network (WLAN) systems.

Band A is an example of a first band. Band A is a frequency band to which time division duplex (TDD) is applied (i.e., a TDD band). According to the Exemplary Embodiment 1, Band A is included in an ultra-high band group (3300 to 5000 MHz). It is noted, however, that Band A is not limited to a frequency band included in the ultra-high band group.

The switch 4A includes a terminal connected to the filter 3A, a terminal connected to the output terminal of the power amplifier 2A, and a terminal connected to an input terminal of a low-noise amplifier (not illustrated). The switch 4A is configured to switch between connecting the filter 3A to the power amplifier 2A and connecting the filter 3A to the low-noise amplifier.

The RFIC 5 is an example of a signal processing circuit that processes a radio frequency signal. In an exemplary aspect, the RFIC 5 performs signal processing such as up-conversion on an input transmission signal to thereby generate a radio frequency transmission signal, and supplies the radio frequency transmission signal to the power amplifier 2A. The RFIC 5 has a control unit that controls the tracker circuit 1A. The function of the RFIC 5 as a control unit may in part or in whole be implemented outside the RFIC 5.

The antenna 6A outputs a transmission signal of Band A received from the power amplifier 2A via the filter 3A. However, it is noted that the antenna 6A is not included in the communication device 7A in an alternative aspect.

The circuit configuration of the communication device 7A illustrated in FIG. 2 is illustrative and not intended to be limiting. For example, the communication device 7A may include a baseband signal processing circuit that performs signal processing by using an intermediate frequency band lower in frequency than the radio frequency signal RF_{A}.

### 1.2 Circuit Configuration of Tracker Circuit 1A

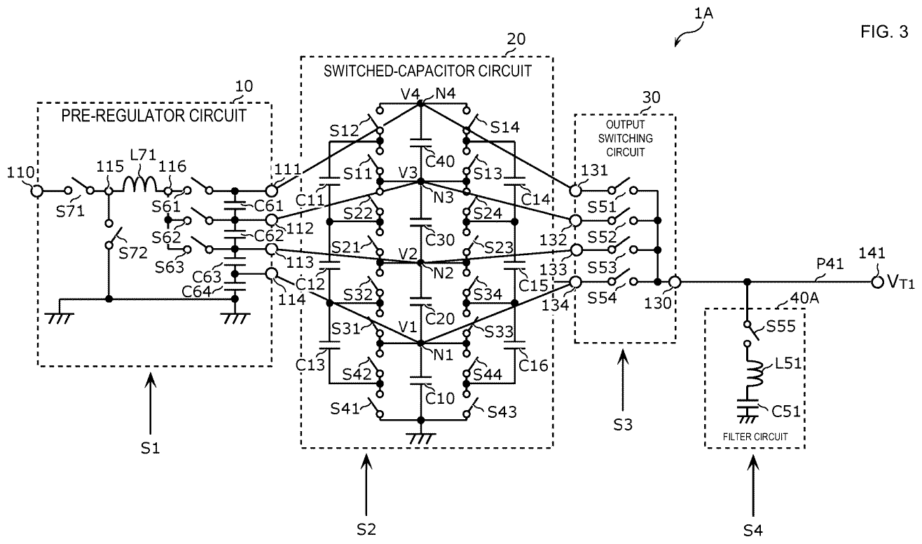

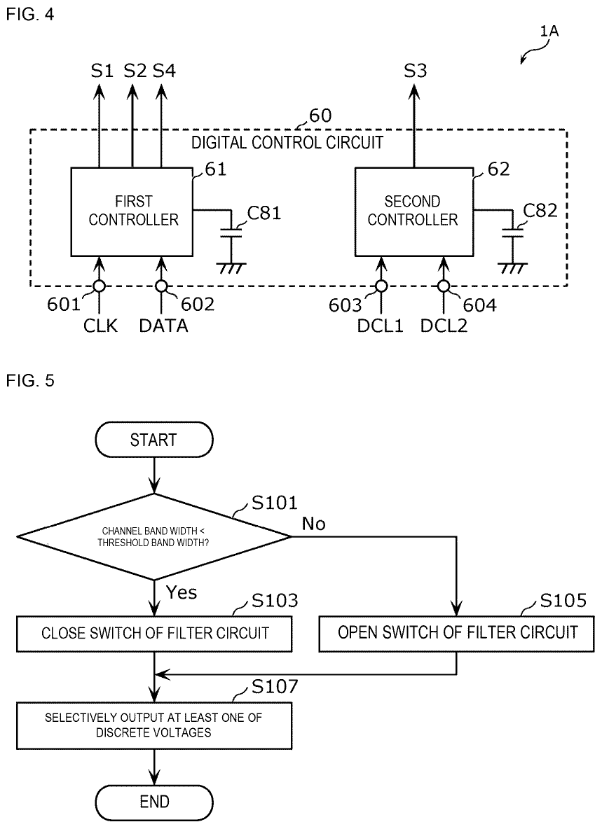

Now, with reference to FIGS. 3 and 4, the circuit configuration of each of the following components included in the tracker circuit 1A will be described: the pre-regulator circuit 10, the switched-capacitor circuit 20, the output switching circuit 30, the filter circuit 40A, and the digital control circuit 60. FIG. 3 is a circuit diagram of the following components according to the Exemplary Embodiment 1: the pre-regulator circuit 10, the switched-capacitor circuit 20, the output switching circuit 30, and the filter circuit 40A. FIG. 4 is a circuit diagram of the digital control circuit 60 according to the Exemplary Embodiment 1.

FIGS. 3 and 4 illustrate exemplary circuit configurations. The pre-regulator circuit 10, the switched-capacitor circuit 20, the output switching circuit 30, the filter circuit 40A, and the digital control circuit 60 may be implemented by using any one of a wide variety of circuit implementations and circuit technologies. Therefore, the description of each circuit provided below is not to be construed restrictively.

### 1.2.1 Circuit Configuration of Switched-Capacitor Circuit 20

First, the circuit configuration of the switched-capacitor circuit 20 is described. As illustrated in FIG. 3, the switched-capacitor circuit 20 includes capacitors C11 to C16, capacitors C10, C20, C30 and C40, and switches S11 to S14, S21 to S24, S31 to S34, and S41 to S44. Energy and charge are input, at nodes N1 to N4, from the pre-regulator circuit 10 to the switched-capacitor circuit 20, and output, at the nodes N1 to N4, from the switched-capacitor circuit 20 to the output switching circuit 30.

Each of the capacitors C11 to C16 functions as a flying capacitor (sometimes also referred to as transfer capacitor). That is, each of the capacitors C11 to C16 is used to step up or step down the first voltage supplied from the pre-regulator circuit 10. In an exemplary aspect, the capacitors C11 to C16 transfer charge between the capacitors C11 to C16 and the nodes N1 to N4 so that voltages V1 to V4 (relative to the ground potential) that satisfy V1:V2:V3:V4=1:2:3:4 are maintained at the four nodes N1 to N4. The voltages V1 to V4 correspond to the second voltages each having a corresponding one of a plurality of discrete voltage levels.

The capacitor C11 has two electrodes. One of the two electrodes of the capacitor C11 is connected to one terminal of the switch S11 and one terminal of the switch S12. The other of the two electrodes of the capacitor C11 is connected to one terminal of the switch S21 and one terminal of the switch S22.

The capacitor C12 has two electrodes. One of the two electrodes of the capacitor C12 is connected to the one terminal of the switch S21 and the one terminal of the switch S22. The other of the two electrodes of the capacitor C12 is connected to one terminal of the switch S31 and one terminal of the switch S32.

The capacitor C13 has two electrodes. One of the two electrodes of the capacitor C13 is connected to the one terminal of the switch S31 and the one terminal of the switch S32. The other of the two electrodes of the capacitor C13 is connected to one terminal of the switch S41 and one terminal of the switch S42.

The capacitor C14 has two electrodes. One of the two electrodes of the capacitor C14 is connected to one terminal of the switch S13 and one terminal of the switch S14. The other of the two electrodes of the capacitor C14 is connected to one terminal of the switch S23 and one terminal of the switch S24.

The capacitor C15 has two electrodes. One of the two electrodes of the capacitor C15 is connected to the one terminal of the switch S23 and the one terminal of the switch S24. The other of the two electrodes of the capacitor C15 is connected to one terminal of the switch S33 and one terminal of the switch S34.

The capacitor C16 has two electrodes. One of the two electrodes of the capacitor C16 is connected to the one terminal of the switch S33 and the one terminal of the switch S34. The other of the two electrodes of the capacitor C16 is connected to one terminal of the switch S43 and one terminal of the switch S44.

A set of the capacitors C11 and C14, a set of the capacitors C12 and C15, and a set of the capacitors C13 and C16 are each configured to be charged and discharged in a complementary manner as a first phase and a second phase are repeated.

In an exemplary aspect, in the first phase, the switches S12, S13, S22, S23, S32, S33, S42, and S43 are turned ON. As a result, for example, one of the two electrodes of the capacitor C12 is connected to the node N3, the other of the two electrodes of the capacitor C12 and the one of the two electrodes of the capacitor C15 are connected to the node N2, and the other of the two electrodes of the capacitor C15 is connected to the node N1.

In the second phase, the switches S11, S14, S21, S24, S31, S34, S41, and S44 are turned ON. As a result, for example, the one of the two electrodes of the capacitor C15 is connected to the node N3, the other of the two electrodes of the capacitor C15 and the one of the two electrodes of the capacitor C12 are connected to the node N2, and the other of the two electrodes of the capacitor C12 is connected to the node N1.

The first phase and the second phase are repeated as described above. Consequently, for example, when one of the capacitors C12 and C15 is being charged from the node N2, the other of the capacitors C12 and C15 can be discharged to the capacitor C30. That is, the capacitors C12 and C15 are configured to be charged and discharged in a complementary manner.

Likewise, as with the set of the capacitors C12 and C15, the set of the capacitors C11 and C14 and the set of the capacitors C13 and C16 are each configured to be charged and discharged in a complementary manner as the first phase and the second phases are repeated.

Each of the capacitors C10, C20, C30, and C40 functions as a smoothing capacitor. That is, the capacitors C10, C20, C30 and C40 are respectively used to hold and smooth the voltages V1 to V4 at the nodes N1 to N4.

The capacitor C10 is connected between the node N1 and ground. In an exemplary aspect, one of two electrodes of the capacitor C10 is connected to the node N1. The other of the two electrodes of the capacitor C10 is connected to ground.

The capacitor C20 is connected between the nodes N2 and N1. In an exemplary aspect, one of two electrodes of the capacitor C20 is connected to the node N2. The other of the two electrodes of the capacitor C20 is connected to the node N1.

The capacitor C30 is connected between the nodes N3 and N2. In an exemplary aspect, one of two electrodes of the capacitor C30 is connected to the node N3. The other of the two electrodes of the capacitor C30 is connected to the node N2.

The capacitor C40 is connected between the nodes N4 and N3. In an exemplary aspect, one of two electrodes of the capacitor C40 is connected to the node N4. The other of the two electrodes of the capacitor C40 is connected to the node N3.

The switch S11 is connected between the one of the two electrodes of the capacitor C11 and the node N3. In an exemplary aspect, the one terminal of the switch S11 is connected to the one of the two electrodes of the capacitor C11. The other terminal of the switch S11 is connected to the node N3.

The switch S12 is connected between the one of the two electrodes of the capacitor C11 and the node N4. In an exemplary aspect, the one terminal of the switch S12 is connected to the one of the two electrodes of the capacitor C11. The other terminal of the switch S12 is connected to the node N4.

The switch S21 is connected between the one of the two electrodes of the capacitor C12 and the node N2. In an exemplary aspect, the one terminal of the switch S21 is connected to the one of the two electrodes of the capacitor C12 and the other of the two electrodes of the capacitor C11. The other terminal of the switch S21 is connected to the node N2.

The switch S22 is connected between the one of the two electrodes of the capacitor C12 and the node N3. In an exemplary aspect, the one terminal of the switch S22 is connected to the one of the two electrodes of the capacitor C12 and the other of the two electrodes of the capacitor C11. The other terminal of the switch S22 is connected to the node N3.

The switch S31 is connected between the other of the two electrodes of the capacitor C12 and the node N1. In an exemplary aspect, the one terminal of the switch S31 is connected to the other of the two electrodes of the capacitor C12 and the one of the two electrodes of the capacitor C13. The other terminal of the switch S31 is connected to the node N1.

The switch S32 is connected between the other of the two electrodes of the capacitor C12 and the node N2. In an exemplary aspect, the one terminal of the switch S32 is connected to the other of the two electrodes of the capacitor C12 and the one of the two electrodes of the capacitor C13. The other terminal of the switch S32 is connected to the node N2. That is, the other terminal of the switch S32 is connected to the other terminal of the switch S21.

The switch S41 is connected between the other of the two electrodes of the capacitor C13 and ground. In an exemplary aspect, the one terminal of the switch S41 is connected to the other of the two electrodes of the capacitor C13. The other terminal of the switch S41 is connected to ground.

The switch S42 is connected between the other of the two electrodes of the capacitor C13 and the node N1. In an exemplary aspect, the one terminal of the switch S42 is connected to the other of the two electrodes of the capacitor C13. The other terminal of the switch S42 is connected to the node N1. That is, the other terminal of the switch S42 is connected to the other terminal of the switch S31.

The switch S13 is connected between the one of the two electrodes of the capacitor C14 and the node N3. In an exemplary aspect, the one terminal of the switch S13 is connected to the one of the two electrodes of the capacitor C14. The other terminal of the switch S13 is connected to the node N3. That is, the other terminal of the switch S13 is connected to the other terminal of the switch S11 and the other terminal of the switch S22.

The switch S14 is connected between the one of the two electrodes of the capacitor C14 and the node N4. In an exemplary aspect, the one terminal of the switch S14 is connected to the one of the two electrodes of the capacitor C14. The other terminal of the switch S14 is connected to the node N4. That is, the other terminal of the switch S14 is connected to the other terminal of the switch S12.

The switch S23 is connected between the one of the two electrodes of the capacitor C15 and the node N2. In an exemplary aspect, the one terminal of the switch S23 is connected to one of the two electrodes of the capacitor C15 and the other of the two electrodes of the capacitor C14. The other terminal of the switch S23 is connected to the node N2. That is, the other terminal of the switch S23 is connected to the other terminal of the switch S21 and the other terminal of the switch S32.

The switch S24 is connected between the one of the two electrodes of the capacitor C15 and the node N3. In an exemplary aspect, the one terminal of the switch S24 is connected to the one of the two electrodes of the capacitor C15 and the other of the two electrodes of the capacitor C14. The other terminal of the switch S24 is connected to the node N3. That is, the other terminal of the switch S24 is connected to the other terminal of the switch S11, the other terminal of the switch S22, and the other terminal of the switch S13.

The switch S33 is connected between the other of the two electrodes of the capacitor C15 and the node N1. In an exemplary aspect, the one terminal of the switch S33 is connected to the other of the two electrodes of the capacitor C15 and the one of the two electrodes of the capacitor C16. The other terminal of the switch S33 is connected to the node N1. That is, the other terminal of the switch S33 is connected to the other terminal of the switch S31 and the other terminal of the switch S42.

The switch S34 is connected between the other of the two electrodes of the capacitor C15 and the node N2. In an exemplary aspect, the one terminal of the switch S34 is connected to the other of the two electrodes of the capacitor C15 and the one of the two electrodes of the capacitor C16. The other terminal of the switch S34 is connected to the node N2. That is, the other terminal of the switch S34 is connected to the other terminal of the switch S21, the other terminal of the switch S32, and the other terminal of the switch S23.

The switch S43 is connected between the other of the two electrodes of the capacitor C16 and ground. In an exemplary aspect, the one terminal of the switch S43 is connected to the other of the two electrodes of the capacitor C16. The other terminal of the switch S43 is connected to ground.

The switch S44 is connected between the other of the two electrodes of the capacitor C16 and the node N1. In an exemplary aspect, the one terminal of the switch S44 is connected to the other of the two electrodes of the capacitor C16. The other terminal of the switch S44 is connected to the node N1. That is, the other terminal of the switch S44 is connected to the other terminal of the switch S31, the other terminal of the switch S42, and the other terminal of the switch S33.

A first set of switches including the switches S12, S13, S22, S23, S32, S33, S42, and S43, and a second set of switches including the switches S11, S14, S21, S24, S31, S34, S41, and S44 are switched between ON and OFF in a complementary manner based on a control signal S2. In an exemplary aspect, in the first phase, the switches in the first set are turned ON, and the switches in the second set are turned OFF. Conversely, in the second phase, the switches in the first set are turned OFF, and the switches in the second set are turned ON.

For example, in one of the first and second phases, charging of the capacitors C10 to C40 from the capacitors C11 to C13 is executed, and in the other of the first and second phases, charging of the capacitors C10 to C40 from the capacitors C14 to C16 is executed. That is, the capacitors C10 to C40 are constantly charged from the capacitors C11 to C13 or the capacitors C14 to C16. This ensures that even when current flows rapidly from the nodes N1 to N4 to the output switching circuit 30, the nodes N1 to N4 are rapidly replenished with charge. This configuration in turn can reduce fluctuations in potential at the nodes N1 to N4.

The operation mentioned above allows a substantially equal voltage to be maintained across each of the capacitors C10, C20, C30, and C40 in the switched-capacitor circuit 20. In an exemplary aspect, the voltages V1 to V4 (relative to the ground potential) that satisfy V1:V2:V3:V4=1:2:3:4 are maintained at the four nodes labeled V1 to V4. The voltage levels of the voltages V1 to V4 correspond to the discrete levels of voltage that can be supplied by the switched-capacitor circuit 20 to the output switching circuit 30.

It is noted that the voltage ratio V1:V2:V3:V4 is not limited to 1:2:3:4. For example, the voltage ratio V1:V2:V3:V4 may be 1:2:4:8 in an alternative aspect.

The configuration of the switched-capacitor circuit 20 illustrated in FIG. 3 is illustrative and not intended to be limiting. In FIG. 3, the switched-capacitor circuit 20 is configured to supply four discrete levels of voltage. This configuration, however, is not intended to be limiting. The switched-capacitor circuit 20 may be configured to supply any number of discrete levels of voltage greater than or equal to two. For example, if the switched-capacitor circuit 20 is to supply two discrete levels of voltage, it may suffice that the switched-capacitor circuit 20 includes at least the capacitors C12 and C15 and the switches S21 to S24 and S31 to S34.

### 1.2.2 Circuit Configuration of Output Switching Circuit 30

The circuit configuration of the output switching circuit 30 will now be described. The output switching circuit 30 is connected to the digital control circuit 60. As illustrated in FIG. 3, the output switching circuit 30 includes input terminals 131 to 134, switches S51 to S54, and an output terminal 130.

The output terminal 130 is connected to the external connection terminal 141. The output terminal 130 is a terminal for supplying a power supply voltage selected from among the voltages V1 to V4 to the power amplifier 2A via the external connection terminal 141.

The input terminals 131 to 134 are respectively connected to the nodes N4 to N1 of the switched-capacitor circuit 20. The input terminals 131 to 134 are terminals for respectively receiving the voltages V4 to V1 from the switched-capacitor circuit 20.

The switch S51 is connected between the input terminal 131 and the output terminal 130. In an exemplary aspect, the switch S51 has a terminal connected to the input terminal 131, and a terminal connected to the output terminal 130. With the connection arrangement mentioned above, the switch S51 is switched between ON and OFF based on a control signal S3 to allow switching between connection and disconnection of the input terminal 131 and the output terminal 130 to and from each other.

The switch S52 is connected between the input terminal 132 and the output terminal 130. In an exemplary aspect, the switch S52 has a terminal connected to the input terminal 132, and a terminal connected to the output terminal 130. With the connection arrangement mentioned above, the switch S52 is switched between ON and OFF based on the control signal S3 to allow switching between connection and disconnection of the input terminal 132 and the output terminal 130 to and from each other.

The switch S53 is connected between the input terminal 133 and the output terminal 130. In an exemplary aspect, the switch S53 has a terminal connected to the input terminal 133, and a terminal connected to the output terminal 130. With the connection arrangement mentioned above, the switch S53 is switched between ON and OFF based on the control signal S3 to allow switching between connection and disconnection of the input terminal 133 and the output terminal 130 to and from each other.

The switch S54 is connected between the input terminal 134 and the output terminal 130. In an exemplary aspect, the switch S54 has a terminal connected to the input terminal 134, and a terminal connected to the output terminal 130. With the connection arrangement mentioned above, the switch S54 is switched between ON and OFF based on the control signal S3 to allow switching between connection and disconnection of the input terminal 134 and the output terminal 130 to and from each other.

The switches S51 to S54 are controlled to be exclusively ON. That is, only one of the switches S51 to S54 is turned ON, with the remainder of the switches S51 to S54 being turned OFF. This allows the output switching circuit 30 to output one voltage selected from among the voltages V1 to V4.

The configuration of the output switching circuit 30 illustrated in FIG. 3 is illustrative and not intended to be limiting. In particular, the switches S51 to S54 may have any configuration that allow at least one of the four input terminals 131 to 134 to be selectively connected to the output terminal 130. In one alternative example, the output switching circuit 30 may further include a switch connected between a set of the switches S51 to S53, and a set of the switch S54 and the output terminal 130. In another alternative example, the output switching circuit 30 may further include a switch connected between a set of the switches S51 and S52, and a set of the switches S53 and S54 and the output terminal 130.

If two discrete levels of voltage are to be supplied from the switched-capacitor circuit 20, the output switching circuit 30 may simply include at least two of the switches S51 to S54.

### 1.2.3 Circuit Configuration of Pre-Regulator Circuit 10

First, the configuration of the pre-regulator circuit 10 is described below. As illustrated in FIG. 3, the pre-regulator circuit 10 includes an input terminal 110, output terminals 111 to 114, inductor connection terminals 115 and 116, switches S61 to S63, S71 and S72, a power inductor L71, and capacitors C61 to C64.

The input terminal 110 is an input terminal for a DC voltage. That is, the input terminal 110 is a terminal for receiving an input voltage from the DC power supply 50.

The output terminal 111 is an output terminal for the voltage V4. That is, the output terminal 111 is a terminal for supplying the voltage V4 to the switched-capacitor circuit 20. The output terminal 111 is connected to the node N4 of the switched-capacitor circuit 20.

The output terminal 112 is an output terminal for the voltage V3. That is, the output terminal 112 is a terminal for supplying the voltage V3 to the switched-capacitor circuit 20. The output terminal 112 is connected to the node N3 of the switched-capacitor circuit 20.

The output terminal 113 is an output terminal for the voltage V2. That is, the output terminal 113 is a terminal for supplying the voltage V2 to the switched-capacitor circuit 20. The output terminal 113 is connected to the node N2 of the switched-capacitor circuit 20.

The output terminal 114 is an output terminal for the voltage V1. That is, the output terminal 114 is a terminal for supplying the voltage V1 to the switched-capacitor circuit 20. The output terminal 114 is connected to the node N1 of the switched-capacitor circuit 20.

The inductor connection terminal 115 is connected to one end of the power inductor L71. The inductor connection terminal 116 is connected to the other end of the power inductor L71.

The switch S71 is connected between the input terminal 110, and the one end of the power inductor L71. In an exemplary aspect, the switch S71 has a terminal connected to the input terminal 110, and a terminal connected to the one end of the power inductor L71 via the inductor connection terminal 115. With the connection arrangement mentioned above, the switch S71 is switched between ON and OFF based on a control signal S1 to allow switching between connection and disconnection of the input terminal 110 and the one end of the power inductor L71 to and from each other.

The switch S72 is connected between the one end of the power inductor L71 and ground. In an exemplary aspect, the switch S72 has a terminal connected to the one end of the power inductor L71 via the inductor connection terminal 115, and a terminal connected to ground. With the connection arrangement mentioned above, the switch S72 can be switched between ON and OFF based on the control signal S1 to allow switching between connection and disconnection of the one end of the power inductor L71 and ground to and from each other.

The switch S61 is connected between the other end of the power inductor L71 and the output terminal 111. In an exemplary aspect, the switch S61 has a terminal connected to the other end of the power inductor L71 via the inductor connection terminal 116, and a terminal connected to the output terminal 111. With the connection arrangement mentioned above, the switch S61 can be switched between ON and OFF based on the control signal S1 to allow switching between connection and disconnection of the other one end of the power inductor L71 and the output terminal 111 to and from each other.

The switch S62 is connected between the other end of the power inductor L71 and the output terminal 112. In an exemplary aspect, the switch S62 has a terminal connected to the other end of the power inductor L71 via the inductor connection terminal 116, and a terminal connected to the output terminal 112. With the connection arrangement mentioned above, the switch S62 can be switched between ON and OFF based on the control signal S1 to allow switching between connection and disconnection of the other one end of the power inductor L71 and the output terminal 112 to and from each other.

The switch S63 is connected between the other end of the power inductor L71 and the output terminal 113. In an exemplary aspect, the switch S63 has a terminal connected to the other end of the power inductor L71 via the inductor connection terminal 116, and a terminal connected to the output terminal 113. With the connection arrangement mentioned above, the switch S63 can be switched between ON and OFF based on the control signal S1 to allow switching between connection and disconnection of the other one end of the power inductor L71 and the output terminal 113 to and from each other.

One of two electrodes of the capacitor C61 is connected to the switch S61 and the output terminal 111. The other of the two electrodes of the capacitor C61 is connected to the switch S62, the output terminal 112, and one of two electrodes of the capacitor C62.

The one of the two electrodes of the capacitor C62 is connected to the switch S62, the output terminal 112, and the other of the two electrodes of the capacitor C61. The other of the two electrodes of the capacitor C62 is connected to a path that connects the switch S63, the output terminal 113, and one of two electrodes of the capacitor C63.

The one of the two electrodes of the capacitor C63 is connected to the switch S63, the output terminal 113, and the other of the two electrodes of the capacitor C62. The other of the two electrodes of the capacitor C63 is connected to the output terminal 114 and one of two electrodes of the capacitor C64.

The one of the two electrodes of the capacitor C64 is connected to the output terminal 114 and the other of the two electrodes of the capacitor C63. The other of the two electrodes of the capacitor C64 is connected to ground.

The switches S61 to S63 are controlled to be exclusively ON. That is, only one of the switches S61 to S63 is turned ON, with the remainder of the switches S61 to S63 being turned OFF. Turning ON only one of the switches S61 to S63 as described above allows the pre-regulator circuit 10 to vary the supply voltage for the switched-capacitor circuit 20 between voltage levels corresponding to the voltages V2 to V4.

The pre-regulator circuit 10 configured as described above is configured to supply charge to the switched-capacitor circuit 20 via at least one of the output terminals 111 to 113.

If an input voltage is to be converted into a single first voltage, the pre-regulator circuit 10 may only need to include at least the switches S71 and S72, and the power inductor L71.

### 1.2.4 Circuit Configuration of Filter Circuit 40A

The circuit configuration of the filter circuit 40A will now be described. The filter circuit 40A is configured to be connectable with the voltage supply path P41. The filter circuit 40A is configured to attenuate noise components from signals (e.g., a plurality of discrete voltages) transmitted through the voltage supply path P41. The filter circuit 40A may be referred to also as pulse shaping circuit or termination circuit.

As illustrated in FIG. 3, the filter circuit 40A is connected in shunt with the voltage supply path P41. That is, the filter circuit 40A is connected between the voltage supply path P41 and ground. The filter circuit 40A includes an inductor L51, a capacitor C51, and a switch S55 that are connected in series.

The inductor L51 is an example of a first inductor. The inductor L51 is connected between the switch S55 and the capacitor C51. In an exemplary aspect, one end of the inductor L51 is connected to the switch S55, and the other end of the inductor L51 is connected to the capacitor C51.

The capacitor C51 is an example of a first capacitor. The capacitor C51 is connected between the inductor L51 and ground. In an exemplary aspect, one end of the capacitor C51 is connected to the inductor L51, and the other end of the capacitor C51 is connected to ground.

The switch S55 is an example of a first switch. The switch S55 is connected between the voltage supply path P41 and the inductor L51. In an exemplary aspect, one terminal of the switch S55 is connected to the voltage supply path P41, and the other terminal of the switch S55 is connected to the inductor L51.

The switch S55 connected as described above is switched between ON and OFF based on a control signal S4. In an exemplary aspect, ON/OFF of the switch S55 is controlled as described below.

(1) When the radio frequency signal RF_{A} has a channel bandwidth (i.e., a modulation bandwidth) greater than or equal to a threshold bandwidth, the switch S55 is opened (turned OFF). The inductor L51 and the capacitor C51 are thus disconnected from the voltage supply path P41. At this time, the discrete voltages V_{T1} are supplied to the power amplifier 2A via the external connection terminal 141, but the filter circuit 40A does not function as a band-reject filter (sometimes referred to also as notch filter) with respect to the voltage supply path P41.

(2) When the radio frequency signal RF_{A} has a channel bandwidth less than the threshold bandwidth, the switch S55 is closed (turned ON). The inductor L51 and the capacitor C51 are thus connected in shunt with the voltage supply path P41. At this time, the voltages V_{T1} are supplied to the power amplifier 2A via the external connection terminal 141, and the filter circuit 40A functions as a band-reject filter with respect to the voltage supply path P41.

The threshold bandwidth used in the above-mentioned control of the switch S55 (an example of a first threshold bandwidth) may be experimentally and/or empirically determined in advance (e.g., 50 MHz).

The stopband of the filter circuit 40A depends on the threshold bandwidth. For example, if 50 MHz is used as the threshold bandwidth, and 1.5 is used as a predetermined coefficient, the stopband of the filter circuit 40A includes a frequency (75 MHz) that is equal to the value of the threshold bandwidth (50 MHz) multiplied by the predetermined coefficient (1.5). This allows the filter circuit 40A to reduce noise components at and around 75 MHz in the voltage supply path P41. This configuration in turn can reduce IMD between the radio frequency signal RF_{A} and noise (75 MHz component) in the power amplifier 2A, and consequently reduce adjacent channel leakage power (ACP) in the power amplifier 2A. The respective values of the threshold bandwidth and the predetermined coefficient mentioned above are illustrative and not intended to be limiting.

The stopband is defined as a band with an insertion loss of 15 dB or more. Accordingly, the stopband of the filter circuit 40A can be determined by measuring the power loss between the output terminal of the output switching circuit 30 and the external connection terminal 141, and detecting a band in which the measured loss is 15 dB or more.

The configuration of the filter circuit 40A illustrated in FIG. 3 is illustrative and not intended to be limiting. For example, the filter circuit 40A need not necessarily include the switch S55 in an alternative aspect. For example, the switch S55 may be connected between the capacitor C51 and ground. According to an exemplary aspect, the filter circuit 40A may be partially or entirely formed by a parasitic reactance and/or a parasitic resistance. The parasitic reactance includes, for example, the inductance and/or capacitance of a metal trace connecting two nodes. The parasitic resistance includes, for example, the resistance of a metal trace connecting two nodes.

### 1.2.5 Circuit Configuration of Digital Control Circuit 60

The circuit configuration of the digital control circuit 60 will now be described. As illustrated in FIG. 4, the digital control circuit 60 incudes a first controller 61, a second controller 62, capacitors C81 and C82, and control terminals 601 to 604.

The first controller 61 is configured to generate the control signals S1, S2, and S4 by processing source-synchronous digital control signals received from the RFIC 5 via the control terminals 601 and 602. The control signal S1 is a signal for controlling the ON/OFF of the switches S61 to S63, S71, and S72 included in the pre-regulator circuit 10. The control signal S2 is a signal for controlling the ON/OFF of the switches S11 to S14, S21 to S24, S31 to S34, and S41 to S44 included in the switched-capacitor circuit 20. The control signal S4 is a signal for controlling the ON/OFF of the switch S55 included in the filter circuit 40A. The first controller 61 may receive an input of a feedback signal for controlling the pre-regulator circuit 10.

It is noted that the digital control signals to be processed by the first controller 61 are not limited to source-synchronous digital control signals. For example, the first controller 61 may process clock-embedded digital control signals in another aspect. Moreover, the first controller 61 may generate a control signal for controlling the output switching circuit 30.

According to the Exemplary Embodiment 1, a single set of a clock signal and a data signal is used as digital control signals for controlling the pre-regulator circuit 10, the switched-capacitor circuit 20, and the filter circuit 40A. This configuration, however, is not intended to be limiting. For example, sets of a clock signal and a data signal may be used individually as digital control signals for controlling the pre-regulator circuit 10, the switched-capacitor circuit 20, and the filter circuit 40A.

The second controller 62 generates the control signal S3 by processing digital control level (DCL) signals (DCL1 and DCL2) received from the RFIC 5 via the control terminals 603 and 604. The DCL signals (DCL1 and DCL2) are generated by the RFIC 5 based on, for example, the envelope signal of a radio frequency signal. The control signal S3 is a signal for controlling the ON/OFF of the switches S51 to S54 included in the output switching circuit 30.

The DCL signals (DCL1 and DCL2) are each a 1-bit signal. The voltages V1 to V4 are each represented by a combination of two 1-bit signals. For example, V1, V2, V3, and V4 are represented by “00”, “01”, “10”, and “11”, respectively. A gray code may be used to represent a voltage level.

The capacitor C81 is connected between the first controller 61 and ground. For example, the capacitor C81 is connected between ground and a power supply line that supplies power to the first controller 61, and functions as a bypass capacitor. The capacitor C82 is connected between the second controller 62 and ground. However, it is noted that the capacitors C81 and C82 are not included in the digital control circuit 60 in an alternative aspect.

According to the Exemplary Embodiment 1, two DCL signals are used to control the output switching circuit 30. The number of DCL signals, however, is not limited to two. For example, one DCL signal, or any number of DCL signals greater than or equal to three may be used in accordance with the number of voltage levels selectable by each output switching circuit 30. The digital control signal to be used for controlling the output switching circuit 30 is not limited to a DCL signal.

### 1.3 Tracking Method

With reference to FIG. 5, a tracking method will now be described, which is a method for supplying a plurality of discrete voltages by the tracker circuit 1A configured as described above. FIG. 5 is a flowchart illustrating a tracking method according to the Exemplary Embodiment 1.

For example, it is determined by the RFIC 5 whether the radio frequency signal RF_{A} has a channel bandwidth less than a threshold bandwidth (S101). If it is determined at this time that the radio frequency signal RF_{A} has a channel bandwidth less than the threshold bandwidth (Yes at S101), the digital control circuit 60 receives a digital control signal indicating that the switch S55 is to be closed, and transmits, to the filter circuit 40A, the control signal S4 for closing the switch S55. As the switch S55 is closed based on the control signal S4, the filter circuit 40A is connected to the voltage supply path P41 (S103).

If it is determined that the radio frequency signal RF_{A} has a channel bandwidth greater than or equal to the threshold bandwidth (No at S101), the digital control circuit 60 receives a digital control signal indicating that the switch S55 is to be opened, and transmits, to the filter circuit 40A, the control signal S4 for opening the switch S55. As the switch S55 is opened based on the control signal S4, the filter circuit 40A is disconnected from the voltage supply path P41 (S105).

With the filter circuit 40A being controlled in this way, the output switching circuit 30 selectively outputs, based on the control signal S3, at least one of a plurality of discrete voltages to the external connection terminal 141 (S107). As a result, at least one of the discrete voltages is selectively supplied to the power amplifier 2A.

### 1.4 Implementation Example of Tracker Circuit 1A

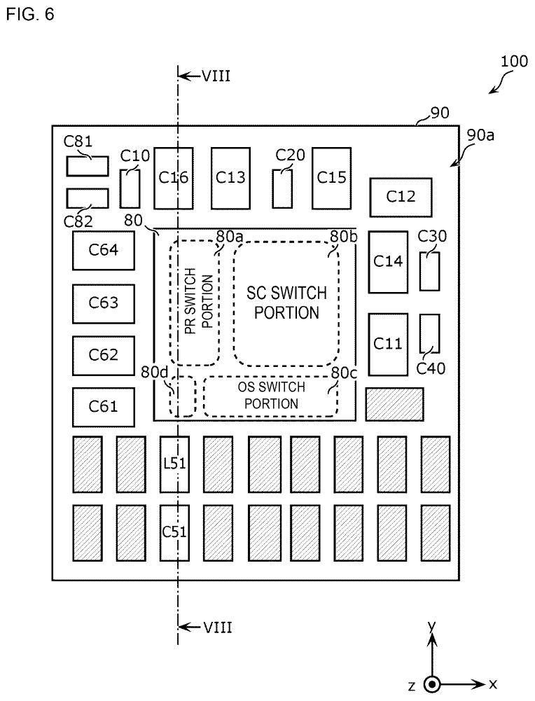

A tracker module 100 will now be described with reference to FIGS. 6 to 8 as an implementation example of the tracker circuit 1A configured as described above. According to the implementation example, the power inductor L71 included in the pre-regulator circuit 10 is not disposed at a module laminate 90. This configuration, however, is not intended to be limiting. That is, the power inductor L71 may be disposed at the module laminate 90.

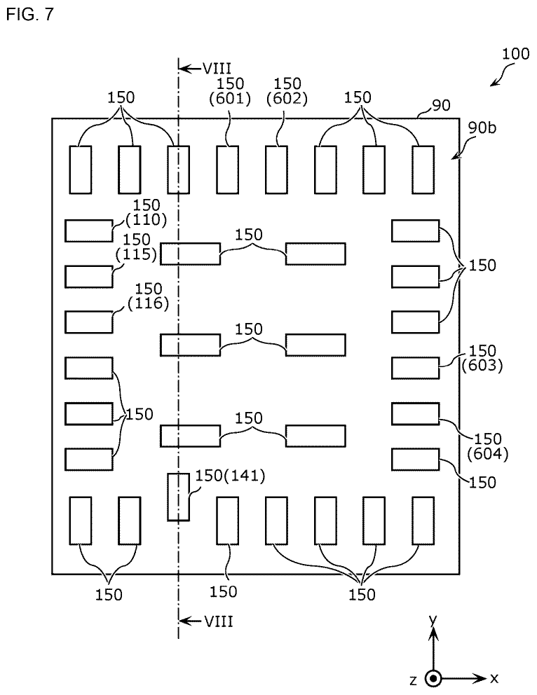

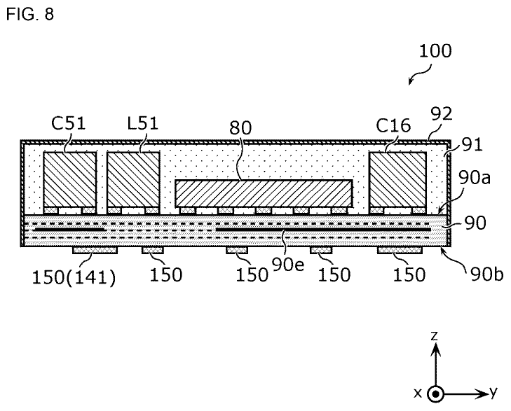

FIG. 6 is a plan view of the tracker module 100 according to the Exemplary Embodiment 1. FIG. 7 is a plan view of the tracker module 100 according to the Exemplary Embodiment 1, with a major face 90b of the module laminate 90 seen through from the positive side of the z-axis. FIG. 8 is a cross-sectional view of the tracker module 100 according to the Exemplary Embodiment 1. The cross-section of the tracker module 100 in FIG. 8 is taken along a line VIII-VIII in each of FIGS. 6 and 7.

In FIGS. 6 to 8, the illustration of some of wiring lines connecting a plurality of circuit components disposed at the module laminate 90 is omitted. In FIGS. 6 and 7, the illustration of a resin member 91 covering the circuit components and a shield electrode layer 92 covering the surface of the resin member 91 is omitted. In FIG. 6, hatched blocks represent some optional circuit components according to exemplary embodiments of the present disclosure.

The tracker module 100 includes the module laminate 90, the resin member 91, the shield electrode layer 92, and a plurality of electrodes 150, in addition to the circuit components including the active and passive elements that are included in the following circuits illustrated in FIGS. 3 and 4: the pre-regulator circuit 10, the switched-capacitor circuit 20, the output switching circuit 30, the filter circuit 40A, and the digital control circuit 60.

The module laminate 90 has opposite major faces 90a and 90b. Aground plane 90e or other components are provided in the module laminate 90 and on the major face 90a. Although the module laminate 90 is depicted in FIGS. 6 and 7 as having a rectangular shape in plan view, it is noted that the shape of the module laminate 90 is not limited to a rectangular shape in alternative aspects.

Suitable examples of the module laminate 90 may include, but are not limited to: a low temperature co-fired ceramics (LTCC) substrate or a high temperature co-fired ceramics (HTCC) substrate that has a multilayer structure of a plurality of dielectric layers; a component-embedded substrate; a substrate with a redistribution layer (RDL); and a printed circuit board.

The following components are disposed on the major face 90a: an integrated circuit 80, the capacitors C10 to C16, C20, C30, C40, C51, C61 to C64, C81, and C82, the inductor L51, and the resin member 91.

The integrated circuit 80 includes a PR switch portion 80a, an SC switch portion 80b, an OS switch portion 80c, and a filter switch portion 80d. The PR switch portion 80a includes the switches S61 to S63, S71, and S72. The SC switch portion 80b includes the switches S11 to S14, S21 to S24, S31 to S34, and S41 to S44. The OS switch portion 80c includes the switches S51 to S54. The filter switch portion 80d includes the switch S55.

In FIG. 6, the PR switch portion 80a, the SC switch portion 80b, the OS switch portion 80c, and the filter switch portion 80d are included in the same single integrated circuit 80. This configuration, however, is not intended to be limiting. In one alternative example, the PR switch portion 80a and the SC switch portion 80b may be included in a single integrated circuit, and the OS switch portion 80c and the filter switch portion 80d may be included in another integrated circuit. In another alternative example, the SC switch portion 80b, the OS switch portion 80c, and the filter switch portion 80d may be included in a single integrated circuit, and the PR switch portion 80a may be included in another integrated circuit. In another alternative example, the PR switch portion 80a, the OS switch portion 80c, and the filter switch portion 80d may be included in a single integrated circuit, and the SC switch portion 80b may be included in another integrated circuit. In another alternative example, the PR switch portion 80a, the SC switch portion 80b, the OS switch portion 80c, and the filter switch portion 80d may be individually included in four different integrated circuits. A plurality of integrated circuits can be manufactured by different process technology nodes.

Although the integrated circuit 80 is depicted in FIG. 6 as having a rectangular shape in plan view of the module laminate 90, the shape of the integrated circuit 80 is not limited to a rectangular shape in alternative aspects.

The integrated circuit 80 is implemented by using, for example, complementary metal oxide semiconductor (CMOS). In an exemplary aspect, the integrated circuit 80 may be manufactured by a silicon on insulator (SOI) process. However, it is noted that the integrated circuit 80 is not limited to CMOS in alternative aspects.

The capacitors C10 to C16, C20, C30, C40, C51, C61 to C64, C81, and C82 are implemented as chip capacitors, which can be a surface mount device (SMD) forming a capacitor. However, the capacitors need not necessarily be implemented as chip capacitors in an alternative aspect. For example, a subset or all of the capacitors may be included in an integrated passive device (IPD), or may be included in the integrated circuit 80 in alternative exemplary aspects.

Moreover, the inductor L51 is implemented as a chip inductor, which can be an SMD forming an inductor. However, the inductor L51 need not necessarily be implemented as a chip capacitor in an alternative aspect. For example, the inductor L51 may be included in an IPD in alternative exemplary aspects.

As described above, the capacitors and the inductor disposed on the major face 90a are grouped for each individual circuit and disposed around the integrated circuit 80.

In an exemplary aspect, a group of the capacitors C61 to C64 included in the pre-regulator circuit 10 is disposed in a region on the major face 90a located between the following two straight lines in plan view of the module laminate 90: a straight line extending along the left side of the integrated circuit 80; and a straight line extending along the left side of the module laminate 90. The group of circuit components included in the pre-regulator circuit 10 is thus disposed near the PR switch portion 80a located within the integrated circuit 80.

A group of the capacitors C10 to C16, C20, C30, and C40 included in the switched-capacitor circuit 20 is disposed in the following two regions on the major face 90a in plan view of the module laminate 90: a region located between a straight line extending along the top side of the integrated circuit 80 and a straight line extending along the top side of the module laminate 90; and a region located between a straight line extending along the right side of the integrated circuit 80 and a straight line extending along the right side of the module laminate 90. The group of circuit components included in the switched-capacitor circuit 20 is thus disposed near the SC switch portion 80b located within the integrated circuit 80. That is, the SC switch portion 80b is disposed closer to the switched-capacitor circuit 20 than is each of the PR switch portion 80a and the OS switch portion 80c.

A group of the capacitor C51 and the inductor L51 included in the filter circuit 40A is disposed in a region on the major face 90a located between the following two lines in plan view of the module laminate 90: a straight line extending along the bottom side of the integrated circuit 80; and a straight line extending along the bottom side of the module laminate 90. The group of circuit components included in the filter circuit 40A is thus disposed near the filter switch portion 80d located within the integrated circuit 80. That is, the filter switch portion 80d is disposed closer to the capacitor C51 and the inductor L51 of the filter circuit 40A than is each of the PR switch portion 80a and the SC switch portion 80b.

The electrodes 150 are disposed on the major face 90b. At least one of the electrodes 150 functions as the external connection terminal 141 illustrated in FIG. 2. The electrodes 150 are electrically connected to the electronic components disposed on the major face 90a via, for example, via-conductors provided in the module laminate 90. The electrodes 150 may be, but are not limited to, copper electrodes. For example, the electrodes may be solder electrodes in alternative aspects.

The resin member 91 covers the major face 90a and at least a subset of the electronic components disposed on the major face 90a. The resin member 91 serves to ensure reliability, such as mechanical strength and moisture resistance, of the electronic components disposed on the major face 90a. However, it is noted that the resin member 91 is not included in the tracker module 100 in an alternative aspect.

The shield electrode layer 92 is an example of a metal layer. The shield electrode layer 92 is a metal thin film formed by, for example, sputtering. The shield electrode layer 92 is provided so as to cover the surface (upper face and lateral faces) of the resin member 91. The shield electrode layer 92 is connected to ground. The shield electrode layer 92 reduces the entry of external noise into the electronic components forming the tracker module 100, and reduces the interference of noise generated in the tracker module 100 with another module or another device. It is noted that the shield electrode layer 92 may not be included in the tracker module 100 in an alternative aspect.

The configuration of the tracker module 100 illustrated in FIGS. 6 to 8 is illustrative and not intended to be limiting. For example, as for the capacitors and the inductor disposed on the major face 90a, a subset of these components may be provided in the module laminate 90. In another example, as for the capacitors and the inductor disposed on the major face 90a, a subset of these components are not included in the tracker module 100, and are not disposed at the module laminate 90 in an alternative aspect.

### 1.5 Technical Effects

As described above, the tracker circuit 1A according to the Exemplary Embodiment 1 includes: the output switching circuit 30 configured to selectively output at least one of a plurality of discrete voltages to the power amplifier 2A; the voltage supply path P41 connecting the output switching circuit 30 and the power amplifier 2A; and the filter circuit 40A connected to the voltage supply path P41. The power amplifier 2A is configured to amplify the radio frequency signal RF_{A} of Band A to which TDD is applied. The filter circuit 40A is connected not in series but in shunt with the voltage supply path P41.

According to the configuration mentioned above, the filter circuit 40A is connected to the voltage supply path P41 that connects the power amplifier 2A and the output switching circuit 30. The power amplifier 2A is configured to amplify the radio frequency signal RF_{A} of Band A to which TDD is applied. This configuration can reduce noise in the voltage supply path P41. This configuration in turn can reduce IMD in the power amplifier 2A used for the TDD band, and consequently reduce spurious emissions to thereby achieve, for example, improved ACPR/ACLR. The filter circuit 40A may be connected not in series but in shunt with the voltage supply path P41. This configuration can reduce loss in the voltage supply path P41, and consequently reduce degradation of the discrete voltages to be supplied to the power amplifier 2A.

In another exemplary aspect, the tracker circuit 1A according to the Exemplary Embodiment 1 includes: the external connection terminal 141 connected to the power amplifier 2A configured to amplify the radio frequency signal RF_{A} of Band A to which TDD is applied; the output switching circuit 30 configured to selectively output at least one of a plurality of discrete voltages to the external connection terminal 141; the voltage supply path P41 connecting the output switching circuit 30 directly to the external connection terminal 141; and the filter circuit 40A connected between the voltage supply path P41 and ground.

According to the configuration mentioned above, the filter circuit 40A is connected to the voltage supply path P41 that connects the external connection terminal 141 and the output switching circuit 30. The external connection terminal 141 is connected to the power amplifier 2A configured to amplify the radio frequency signal RF_{A} of Band A to which TDD is applied. This configuration can reduce noise in the voltage supply path P41. This can also reduce IMD in the power amplifier 2A used for the TDD band, and consequently reduce spurious emissions to thereby achieve, for example, improved ACPR/ACLR. The filter circuit 40A is connected between the voltage supply path P41 and ground. The output switching circuit 30 and the external connection terminal 141 are directly connected by the voltage supply path P41. This configuration can reduce loss in the voltage supply path P41, and consequently reduce degradation of the discrete voltages in the voltage supply path P41.

For example, in the tracker circuit 1A according to the Exemplary Embodiment 1, the filter circuit 40A may include the inductor L51, the capacitor C51, and the switch S55 that are connected in series. The inductor L51 and the capacitor C51 may be connected in shunt with the voltage supply path P41 via the switch S55.

That is, in the tracker circuit 1A according to the Exemplary Embodiment 1, the filter circuit 40A may include the inductor L51, the capacitor C51, and the switch S55 that are connected in series, and the inductor L51 and the capacitor C51 may be connected between the voltage supply path P41 and ground via the switch S55.

According to the configuration mentioned above, the switch S55 is included in the filter circuit 40A. This configuration can switch between connection and disconnection of the inductor L51 and the capacitor C51 to and from the voltage supply path P41. This can switch between prioritizing reduced noise in the voltage supply path P41, and prioritizing reduced degradation of the discrete voltages in the voltage supply path P41.

For example, in the tracker circuit 1A according to the Exemplary Embodiment 1, when the radio frequency signal RF_{A} has a channel bandwidth greater than or equal to a threshold bandwidth, the switch S55 may be opened, and when the radio frequency signal RF_{A} has a channel bandwidth less than the threshold bandwidth, the switch S55 may be closed.

According to the configuration mentioned above, the switch S55 of the filter circuit 40A is closed when the radio frequency signal RF_{A} has a narrow channel bandwidth. When a channel has a narrow bandwidth, the distance (in frequency) from the center frequency of the channel to an adjacent channel is short, and thus the frequencies that cause IMD affecting ACP are low. In this regard, when a plurality of discrete voltages are to be supplied, noise increases with decreasing frequency in the voltage supply path P41. Consequently, a narrow channel bandwidth results in increased noise at the frequencies that cause IMD affecting ACP. Accordingly, when the channel bandwidth is narrow, the switch S55 is closed. This configuration can prioritize reduction of the noise at the frequencies that cause IMD affecting ACP, and thus effectively reduce spurious emissions (i.e., ACP) in the power amplifier 2A. When the radio frequency signal RF_{A} has a wide channel bandwidth, the switch S55 of the filter circuit 40A is opened. When the channel bandwidth is wide, the discrete voltages change rapidly, and thus the voltage supply path P41 is required to have higher responsiveness. Accordingly, when the channel bandwidth is wide, the switch S55 is opened. This can reduce degradation of the responsiveness of the voltage supply path P41, and thus effectively reduce degradation of the discrete voltages in the voltage supply path P41.

For example, in the tracker circuit 1A according to the Exemplary Embodiment 1, the filter circuit 40A may have a stopband that depends on the threshold bandwidth.

The configuration mentioned above achieves a stopband adapted to a channel bandwidth that is less than the threshold bandwidth at which the switch S55 is closed and the filter circuit 40A is enabled. This allows for effective reduction of spurious emissions in the power amplifier 2A.

In the tracker circuit 1A according to the Exemplary Embodiment 1, Band A may be included in the range of 3300 to 5000 MHz.

The configuration mentioned above can switch between connection and disconnection of the filter circuit 40A to and from the voltage supply path P41, which is used for Band A with a greater available channel bandwidth and higher in frequency than Band B. This means that disconnecting the filter circuit 40A results in pronounced reduction of degradation of the discrete voltages.

A tracking method according to the Exemplary Embodiment 1 includes: when the radio frequency signal RF_{A} that is to be amplified by the power amplifier 2A and that is in Band A to which TDD is applied has a channel bandwidth greater than or equal to a threshold bandwidth, disconnecting the filter circuit 40A from the voltage supply path P41; and when the channel bandwidth is less than the threshold bandwidth, connecting the filter circuit 40A to the voltage supply path P41; and selectively supplying at least one of a plurality of discrete voltages to the power amplifier 2A via the voltage supply path P41.

The configuration mentioned above enables the filter circuit 40A to be connected to the voltage supply path P41 when the radio frequency signal RF_{A} has a narrow channel bandwidth. When a channel has a narrow bandwidth, the distance (e.g., in frequency) from the center frequency of the channel to an adjacent channel is short, and thus the frequencies that cause IMD affecting ACP are low. In this regard, when a plurality of discrete voltages are to be supplied, noise increases with decreasing frequency in the voltage supply path P41. Consequently, a narrow channel bandwidth results in increased noise at the frequencies that cause IMD affecting ACP. Accordingly, when the channel bandwidth is narrow, the filter circuit 40A is connected to the voltage supply path P41. This configuration can prioritize reduction of the noise at the frequencies that cause IMD affecting ACP, and thus effectively reduce spurious emissions (i.e., ACP) in the power amplifier 2A. When the radio frequency signal RF_{A} has a wide channel bandwidth, the filter circuit 40A can be disconnected from the voltage supply path P41. When the channel bandwidth is wide, the discrete voltages change rapidly, and thus the voltage supply path P41 is required to have higher responsiveness. Therefore, disconnecting the filter circuit 40A from the voltage supply path P41 when the channel bandwidth is wide can reduce degradation of the responsiveness of the voltage supply path P41, and thus effectively reduce degradation of the discrete voltages in the voltage supply path P41.

In the circuit configuration in each of FIGS. 2 and 3, the tracker circuit 1A may further include any plurality of additional filter circuits on the voltage supply path P41. For example, the tracker circuit 1A may include any additional filter circuit that is connected at one end to the output switching circuit 30 and that is connected at the other end to the filter circuit 40A and the external connection terminal 141, and/or any additional filter circuit that is connected at one end to the output switching circuit 30 and the filter circuit 40A and that is connected at the other end to the external connection terminal 141. As with, for example, the filter circuit 40A, such any additional filter circuits may include an inductor, a capacitor, and a switch.

### Exemplary Embodiment 2

The Exemplary Embodiment 2 will now be described. A tracker circuit according to the Exemplary Embodiment 2 differs from the tracker circuits according to the Exemplary Embodiment 1 mainly in that the tracker circuit is configured to supply a plurality of discrete voltages to two different power amplifiers. The tracker circuit according to the Exemplary Embodiment 2 will be described below with reference to the drawings, with focus on differences from the Exemplary Embodiment 1.

### 2.1 Circuit Configuration of Communication Device 7B

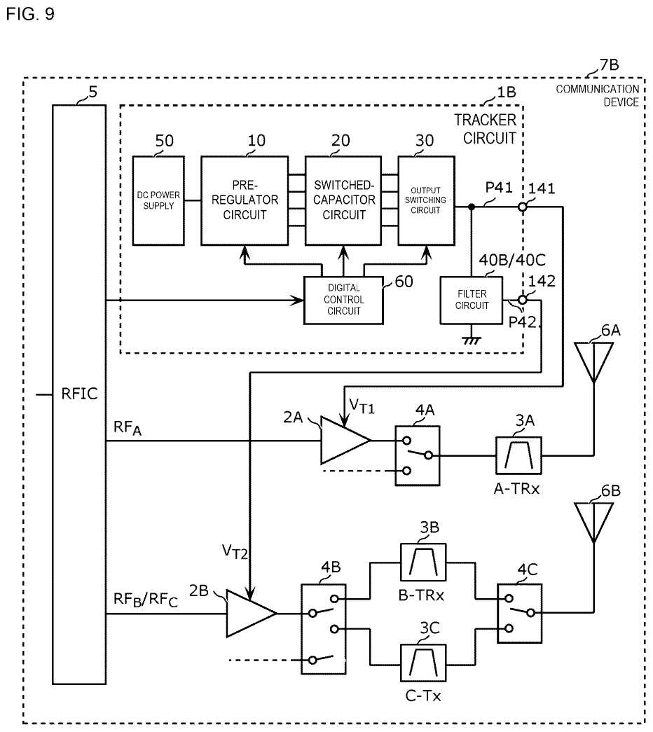

First, a communication device 7B according to the Exemplary Embodiment 2 will be described with reference to FIG. 9. FIG. 9 is a circuit diagram of the communication device 7B according to the Exemplary Embodiment 2.

FIG. 9 illustrates an exemplary circuit configuration. The communication device 7B may be implemented by using any one of a wide variety of circuit implementations and circuit technologies. Therefore, the description of the communication device 7B provided below is not to be construed restrictively.

As illustrated in FIG. 9, the communication device 7B includes a tracker circuit 1B, power amplifiers 2A and 2B, filters 3A to 3C, switches 4A to 4C, an RFIC 5, and antennas 6A and 6B.

The tracker circuit 1B is configured to supply the power amplifier 2A with a plurality of discrete voltages V_{T1} based on a tracking mode. The tracker circuit 1B is further configured to supply the power amplifier 2B with a plurality of discrete voltages V_{T2} based on a tracking mode. As illustrated in FIG. 9, the tracker circuit 1B includes a pre-regulator circuit 10, a switched-capacitor circuit 20, an output switching circuit 30, a filter circuit 40B, a DC power supply 50, a digital control circuit 60, and external connection terminals 141 and 142.

The external connection terminal 142 is an example of a second external connection terminal. The external connection terminal 142 is connected at a location outside the tracker circuit 1B to the power amplifier 2B, and connected at a location inside the tracker circuit 1B to the output switching circuit 30 via a voltage supply path P42.

The voltage supply path P42 is an example of a second voltage supply path. The voltage supply path P42 is part of a path connecting the output switching circuit 30 and the power amplifier 2B. In this case, the voltage supply path P42 is a path directly connecting the output switching circuit 30 and the external connection terminal 142.

The power amplifier 2B is an example of a second power amplifier. The power amplifier 2B is connected between the RFIC 5 and the filters 3B and 3C. Further, the power amplifier 2B is connected to the tracker circuit 1B. The power amplifier 2B is configured to amplify, by using the discrete voltages V_{T2} received from the tracker circuit 1B, the following signals received from the RFIC 5: a radio frequency signal RF_{B} (an example of a second radio frequency signal) of Band B; and a radio frequency signal RF_{C} (an example of a third radio frequency signal) of Band C.

The filter 3B is connected between the power amplifier 2B and the antenna 6B. The filter 3B is a band pass filter with a passband that includes Band B.

The filter 3C is connected between the power amplifier 2B and the antenna 6B. The filter 3C is a band pass filter with a passband that includes the transmission band of Band C.

Bands B and C are frequency bands for communication systems built by using radio access technology (RAT). Bands B and C are predefined by standardizing bodies or other entities. Band B is an example of a second band, and is a frequency band to which TDD is applied. Band C is an example of a third band, and is a frequency band to which FDD is applied (i.e., an FDD band). According to the Exemplary Embodiment 2, Bands B and C are included in a mid-high band group (1427 to 2690 MHz). It is noted that Bands B and C are not limited to frequency bands included in the mid-high band group.

The switch 4B includes a terminal connected to the output terminal of the power amplifier 2B, a terminal connected to one end of the filter 3B, and a terminal connected to one end of the filter 3C. Further, as required, the switch 4B includes a terminal connected to the input terminal of a low-noise amplifier (not illustrated). The switch 4B is configured to switch between connecting the power amplifier 2B to the filter 3B and connecting the power amplifier 2B to the filter 3C. Further, the switch 4B may be configured to switch between connecting the filter 3B to the power amplifier 2B and connecting the filter 3B to the low-noise amplifier.

The switch 4C includes a terminal connected to the antenna 6B, a terminal connected to the filter 3B, and a terminal connected to the filter 3C. The switch 4C is configured to switch between connecting the antenna 6B to the filter 3B and connecting the antenna 6B to the filter 3C.

The antenna 6B outputs transmission signals of Bands B and C received from the power amplifier 2B via the filters 3B and 3C. However, it is noted that the antenna 6B is not included in the communication device 7B in an alternative aspect.

The communication device 7B may further include a filter with a passband that includes the reception band of Band C. In this case, the filter may be implemented as a duplexer together with the filter 3C.

### 2.2. Circuit Configuration of Filter Circuit 40B

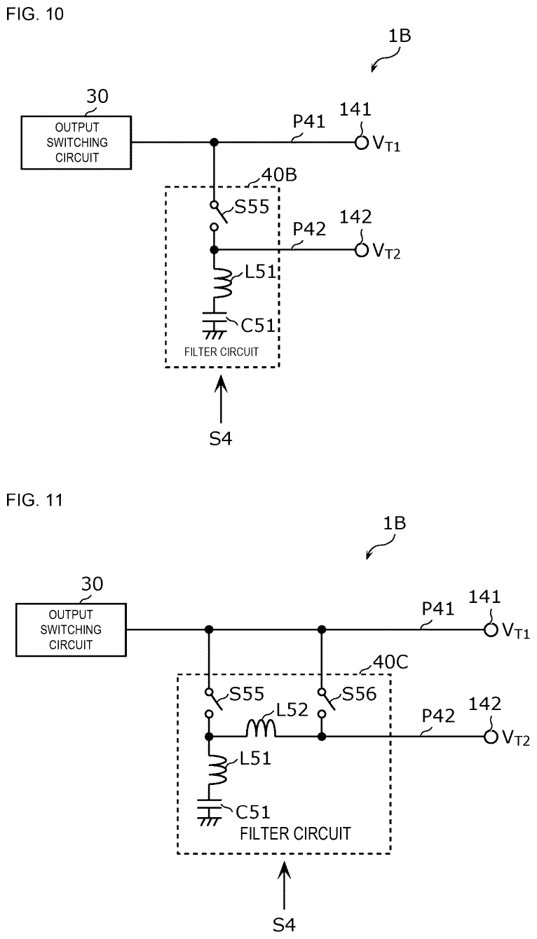

The circuit configuration of the filter circuit 40B included in the tracker circuit 1B will now be described with reference to FIG. 10. FIG. 10 is a circuit diagram of the filter circuit 40B according to the Exemplary Embodiment 2.

FIG. 10 illustrates an exemplary circuit configuration. The filter circuit 40B may be implemented by using any one of a wide variety of circuit implementations and circuit technologies. Therefore, the description of the filter circuit 40B provided below is not to be construed restrictively.

The filter circuit 40B is a pulse shaping network. The filter circuit 40B is configured to be connectable in shunt with the voltage supply paths P41 and P42. The filter circuit 40B is configured to attenuate noise components from signals (a plurality of discrete voltages) transmitted through the voltage supply paths P41 and P42. In an exemplary aspect, as illustrated in FIG. 10, the filter circuit 40B includes an inductor L51, a capacitor C51, and a switch S55 that are connected in series.

The inductor L51 is an example of a first inductor. The inductor L51 is connected between the voltage supply path P42 and the capacitor C51. In an exemplary aspect, one end of the inductor L51 is connected to a portion of the voltage supply path P42 that is located between the switch S55 and the external connection terminal 142. The other end of the inductor L51 is connected to the capacitor C51.

The capacitor C51 is an example of a first capacitor. The capacitor C51 is connected between the inductor L51 and ground. In an exemplary aspect, one end of the capacitor C51 is connected to the inductor L51, and the other end of the capacitor C51 is connected to ground.

The switch S55 is an example of a first switch. The switch S55 is connected between the output switching circuit 30 and the external connection terminal 142, and between the voltage supply path P41 and the inductor L51. In an exemplary aspect, one terminal of the switch S55 is connected to the voltage supply path P41, and the other terminal of the switch S55 is connected to the inductors L51 and the external connection terminal 142.

The switch S55 connected as described above is switched between ON and OFF based on a control signal S4. In an exemplary aspect, ON/OFF of the switch S55 is controlled as described below.

(1) In a case where the radio frequency signal RF_{A} is to be amplified by the power amplifier 2A and the radio frequency signals RF_{B} and RF_{C} are not to be amplified by the power amplifier 2B, when the radio frequency signal RF_{A} has a channel bandwidth greater than or equal to a threshold bandwidth, the switch S55 is opened. The inductor L51 and the capacitor C51 are thus disconnected from the voltage supply path P41. At this time, the discrete voltages V_{T1} are supplied to the power amplifier 2A via the external connection terminal 141, but the filter circuit 40B does not function as a band-reject filter with respect to the voltage supply path P41.

(2) In a case where the radio frequency signal RF_{A} is to be amplified by the power amplifier 2A and the radio frequency signals RF_{B} and RF_{C} are not to be amplified by the power amplifier 2B, when the radio frequency signal RF_{A} has a channel bandwidth less the threshold bandwidth, the switch S55 is closed. The inductor L51 and the capacitor C51 are thus connected in shunt with the voltage supply path P41. At this time, the voltages V_{T1} are supplied to the power amplifier 2A via the external connection terminal 141, and the filter circuit 40B functions as a band-reject filter with respect to the voltage supply path P41.

(3) In a case where the radio frequency signal RF_{B} or RF_{C} is to be amplified by the power amplifier 2B and the radio frequency signal RF_{A} is not to be amplified by the power amplifier 2A, the switch S55 is closed. The inductor L51 and the capacitor C51 are thus connected in shunt with the voltage supply path P42. At this time, the voltages V_{T2} are supplied to the power amplifier 2B via the external connection terminal 142, and the filter circuit 40B functions as a band-reject filter with respect to the voltage supply path P42.

The threshold bandwidth to be used in the above-mentioned control of the switch S55 may be a threshold bandwidth similar to that according to the Exemplary Embodiment 1.

### 2.3 Technical Effects

As described above, in the tracker circuit 1B according to the Exemplary Embodiment 2, the output switching circuit 30 may further be configured to selectively output at least one of the discrete voltages to the power amplifier 2B. The power amplifier 2B may be configured to amplify at least one of the radio frequency signal RF_{B} of Band B to which TDD is applied or the radio frequency signal RF_{C} of Band C to which FDD is applied. The tracker circuit 1B may further include the voltage supply path P42 connecting the output switching circuit 30 and the power amplifier 2B. The inductor L51 and the capacitor C51 may be connected in shunt with the voltage supply path P42. The switch S55 may be connected in series with the voltage supply path P42.

That is, the tracker circuit 1B according to the Exemplary Embodiment 2 may further include: the external connection terminal 142 connected to the power amplifier 2B, the power amplifier 2B being configured to amplify at least one of the radio frequency signal RF_{B} of Band B to which TDD is applied or the radio frequency signal RF_{C} of Band C to which FDD is applied; and the voltage supply path P42 connecting the output switching circuit 30 and the external connection terminal 142. The switch S55 may be connected between the output switching circuit 30 and the external connection terminal 142. The inductor L51 and the capacitor C51 may be connected between ground, and a portion of the voltage supply path P42 that is located between the switch S55 and the external connection terminal 142.

The inductor L51 and the capacitor C51 are thus connected in shunt with the voltage supply path P42 in addition to the voltage supply path P41. This configuration achieves, for the voltage supply path P42 as well, an effect similar to that for the voltage supply path P41. Further, the inductor L51 and the capacitor C51 are shared between the two voltage supply paths P41 and P42. This helps to mitigate an increase in the number of circuit elements.

For example, in the tracker circuit 1B according to the Exemplary Embodiment 2, in a case where the radio frequency signal RF_{A} is to be amplified by the power amplifier 2A, (i) when the radio frequency signal RF_{A} has a channel bandwidth greater than or equal to a threshold bandwidth, the switch S55 may be opened, and (ii) when the radio frequency signal RF_{A} has a channel bandwidth less than the threshold bandwidth, the switch S55 may be closed. In a case where the radio frequency signal RF_{B} or the radio frequency signal RF_{C} is to be amplified by the power amplifier 2B, the switch S55 may be closed.

According to the configuration mentioned above, in a case where the radio frequency signal RF_{A} is to be amplified by the power amplifier 2A, when the radio frequency signal RF_{A} has a narrow channel bandwidth, the switch S55 of the filter circuit 40B is closed. When a channel has a narrow bandwidth, the distance (e.g., in frequency) from the center frequency of the channel to an adjacent channel is short, and thus the frequencies that cause IMD affecting ACP shift are low. In this regard, when a plurality of discrete voltages are to be supplied, noise increases with decreasing frequency in the voltage supply path P41. Consequently, a narrow channel bandwidth results in increased noise at the frequencies that cause IMD affecting ACP. Accordingly, when the channel bandwidth is narrow, the switch S55 is closed. This configuration can prioritize reduction of the noise at the frequencies that cause IMD affecting ACP, and effectively reduce spurious emissions in the power amplifier 2A. In a case where the radio frequency signal RF_{A} is to be amplified by the power amplifier 2A, when the radio frequency signal RF_{A} has a wide channel bandwidth, the switch S55 of the filter circuit 40B is opened. When the channel bandwidth is wide, the discrete voltages change rapidly, and thus the voltage supply path P41 is required to have higher responsiveness. Accordingly, when the channel bandwidth is wide, the switch S55 is opened. This configuration can reduce degradation of the responsiveness of the voltage supply path P41, and thus effectively reduce degradation of the discrete voltages in the voltage supply path P41. Further, in a case where the radio frequency signal RF_{B} or RF_{C} is to be amplified by the power amplifier 2B, the switch S55 of the filter circuit 40B is closed. This configuration can reduce, in the voltage supply path P42, noise at the frequencies that cause IMD affecting ACP and/or the reception band. This in turn contributes to reduction of spurious emissions in the power amplifier 2B and/or improvement of reception sensitivity.

For example, in the tracker circuit 1B according to the Exemplary Embodiment 2, Band A may be included in the range of 3300 to 5000 MHz, and Bands B and C may each be included in the range of 1427 to 2690 MHz.

The configuration mentioned above can switch between connection and disconnection of the filter circuit 40B to and from the voltage supply path P41, which is used for Band A with a greater available channel bandwidth and higher in frequency than Band B. This allows for greater reduction of the degradation of the discrete voltages in the voltage supply path P41. As for the voltage supply path P42, which is used for Band B and/or Band C for which a greater channel bandwidth is not available, the filter circuit 40B can be connected to the voltage supply path P42 regardless of the channel bandwidth. This configuration can prioritize reduction of the noise at the frequencies that cause IMD affecting ACP, and thus effectively reduce spurious emissions in the power amplifier 2B.

### Modification of the Exemplary Embodiment 2

A modification of the Exemplary Embodiment 2 will now be described. The modification differs from the Exemplary Embodiment 2 mainly in the configuration of the filter circuit. A tracker circuit according to the modification will be described below with reference to the drawings, with focus on differences from the Exemplary Embodiment 2.

### 2.4 Circuit Configuration of Filter Circuit 40C

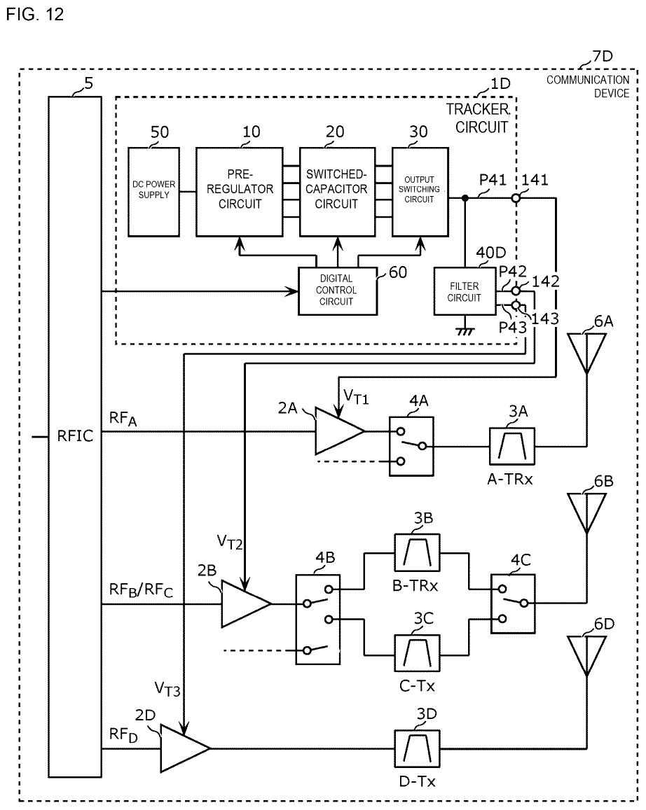

The circuit configuration of a filter circuit 40C included in the tracker circuit 1B according to the modification will now be described with reference to FIGS. 9 and 11. FIG. 11 is a circuit diagram of the filter circuit 40C according to the modification.

FIG. 11 illustrates an exemplary circuit configuration. The filter circuit 40C may be implemented by using any one of a wide variety of circuit implementations and circuit technologies. Therefore, the description of the filter circuit 40C provided below is not to be construed restrictively.

The filter circuit 40C is a pulse shaping network. The filter circuit 40C is configured to be connectable with the voltage supply paths P41 and P42. The filter circuit 40C is configured to attenuate noise components from signals (a plurality of discrete voltages) transmitted through the voltage supply paths P41 and P42. In an exemplary aspect, as illustrated in FIG. 11, the filter circuit 40C includes an inductor L52 and a switch S56, in addition to the inductor L51, the capacitor C51, and the switch S55.

The inductor L52 is an example of a second inductor. The inductor L52 is connected between the switch S55 and the external connection terminal 142, and between the switch S56 and the inductor L51. In an exemplary aspect, one end of the inductor L52 is connected to the switch S55 and the inductor L51, and the other end of the inductor L52 is connected to the switch S56 and the external connection terminal 142.

The switch S56 is connected in series with a path connecting the voltage supply paths P41 and P42. In an exemplary aspect, one terminal of the switch S56 is connected to the voltage supply path P41, and the other terminal of the switch S56 is connected to a portion of the voltage supply path P42 that is located between the inductor L52 and the external connection terminal 142.

As with the switch S55, the switch S56 connected as described above is switched between ON and OFF based on the control signal S4. In an exemplary aspect, ON/OFF of the switches S55 to S56 is controlled as described below.

(1) In a case where the radio frequency signal RF_{A} is to be amplified by the power amplifier 2A and the radio frequency signals RF_{B} and RF_{C} are not to be amplified by the power amplifier 2B, when the radio frequency signal RF_{A} has a channel bandwidth greater than or equal to a first threshold bandwidth, the switches S55 and S56 are opened. The inductors L51 and L52, and the capacitor C51 are thus disconnected from the voltage supply path P41. At this time, the discrete voltages V_{T1} are supplied to the power amplifier 2A via the external connection terminal 141, but the filter circuit 40C does not function as a band-reject filter with respect to the voltage supply path P41.

(2) In a case where the radio frequency signal RF_{A} is to be amplified by the power amplifier 2A and the radio frequency signals RF_{B} and RF_{C} are not to be amplified by the power amplifier 2B, when the radio frequency signal RF_{A} has a channel bandwidth greater than or equal to a second threshold bandwidth and less than the first threshold bandwidth, the switch S55 is closed, and the switch S56 is opened. The inductor L51 and the capacitor C51 are thus connected in shunt with the voltage supply path P41. At this time, the discrete voltages V_{T1} are supplied to the power amplifier 2A via the external connection terminal 141, and the filter circuit 40C functions as a first band-reject filter with respect to the voltage supply path P41, which is a band-reject filter with a first stopband that depends on the first threshold bandwidth. For example, when the first threshold bandwidth is 50 MHz, the first stopband is a stopband including a frequency (75 MHz) that is equal to the value of the first threshold bandwidth (50 MHz) multiplied by a predetermined coefficient (1.5).

(3) In a case where the radio frequency signal RF_{A} is to be amplified by the power amplifier 2A and the radio frequency signals RF_{B} and RF_{C} are not to be amplified by the power amplifier 2B, when the radio frequency signal RF_{A} has a channel bandwidth less than the second threshold bandwidth, the switch S55 is opened, and the switch S56 is closed. The inductors L52 and L51 and the capacitor C51 are thus connected in shunt with the voltage supply path P41. At this time, the discrete voltages V_{T1} are supplied to the power amplifier 2A via the external connection terminal 141, and the second circuit 40C functions as a second band-reject filter with respect to the voltage supply path P41, which is a band-reject filter with a second stopband that depends on the second threshold bandwidth. For example, when the second threshold bandwidth is 20 MHz, the second stopband is a stopband including a frequency (30 MHz) that is equal to the value of the second threshold bandwidth (20 MHz) multiplied by a predetermined coefficient (1.5).

(4) In a case where the radio frequency signal RF_{B} is to be amplified by the power amplifier 2B and the radio frequency signal RF_{A} is not to be amplified by the power amplifier 2A, when the radio frequency signal RF_{B} has a channel bandwidth greater than or equal to the second threshold bandwidth, the switch S55 is closed, and the switch S56 is opened. Thus, the inductor L51 and the capacitor C51 are connected in shunt with the voltage supply path P42, and the inductor L52 is connected in series with the voltage supply path P42. At this time, the discrete voltages V_{T2} are supplied to the power amplifier 2B via the external connection terminal 142, and the filter circuit 40C functions as a third band-reject filter with a third stopband with respect to the voltage supply path P42.

(5) In a case where the radio frequency signal RF_{B} is to be amplified by the power amplifier 2B and the radio frequency signal RF_{A} is not to be amplified by the power amplifier 2A, when the radio frequency signal RF_{B} has a channel bandwidth less than the second threshold bandwidth, the switch S55 is opened, and the switch S56 is closed. The inductors L52 and L51 and the capacitor C51 are thus connected in shunt with the voltage supply path P42. At this time, the discrete voltages V_{T2} are supplied to the power amplifier 2B via the external connection terminal 142, and the filter circuit 40C functions as a second band-reject filter with a second stopband with respect to the voltage supply path P42.

(6) In a case where the radio frequency signal RF_{C} is to be amplified by the power amplifier 2B and the radio frequency signal RF_{A} is not to be amplified by the power amplifier 2A, the switch S55 is closed, and the switch S56 is opened. Thus, the inductor L51 and the capacitor C51 are connected in shunt with the voltage supply path P42, and the inductor L52 is connected in series with the voltage supply path P42. At this time, the discrete voltages V_{T2} are supplied to the power amplifier 2B via the external connection terminal 142, and the filter circuit 40C functions as a third band-reject filter with a third stopband with respect to the voltage supply path P42.

The first threshold bandwidth and the second threshold bandwidth to be used in the above-mentioned control of the switches S55 and S56 may be experimentally and/or empirically determined in advance. The first threshold bandwidth to be used may be a frequency bandwidth (e.g., 100 MHz) greater than the second threshold bandwidth, and the second threshold bandwidth to be used may be a frequency bandwidth (e.g., 50 MHz) less than the first threshold bandwidth.

With the above-described switch control, the filter circuit 40C functions as a variable band-reject filter with a stopband that varies with the channel bandwidth.

The above-mentioned respective values of the first threshold bandwidth, the second threshold bandwidth, and the predetermined coefficient are illustrative and not intended to be limiting.

### 2.5 Advantageous Effects

As described above, in the tracker circuit 1B according to the modification, the filter circuit 40C may further include: the inductor L52 connected in series with a portion of the voltage supply path P42 that is located between the switch S55 and the power amplifier 2B; and the switch S56 connected in series with a path connecting the voltage supply paths P41 and P42. One terminal of the switch S56 may be connected to the voltage supply path P41, and the other terminal of the switch S56 may be connected to a portion of the voltage supply path P42 that is located between the inductor L52 and the power amplifier 2B.

According to the configuration mentioned above, the switches S55 and S56 enable switching of connections between the inductor L52 and the voltage supply paths P41 and P42. This allows the stopband of the filter circuit 40C to be varied. In particular, as for the voltage supply path P41, the two switches S55 and S56 enable switching between the following states: disconnecting the inductors L51 and L52 and the capacitor C51 from the voltage supply path P41; connecting, in shunt with the voltage supply path P41, the inductor L51 and the capacitor C51; and connecting, in shunt with the voltage supply path P41, the inductors L51 and L52 and the capacitor C51. As for the voltage supply path P42, the two switches S55 and S56 enable switching between the following states: connecting, in shunt with the voltage supply path P42, the inductor L51 and the capacitor C51, and connecting the inductor L52 in series with the voltage supply path P42; and connecting, in shunt with the voltage supply path P42, the inductors L51 and L52 and the capacitor C51. In this way, for the filter circuit 40C, the two switches S55 and S56 can achieve switching between a plurality of stopbands with respect to the two voltage supply paths P41 and P42.

For example, in the tracker circuit 1B according to the modification, in a case where the radio frequency signal RF_{A} is to be amplified by the power amplifier 2A, (i) when the radio frequency signal RF_{A} has a channel bandwidth greater than or equal to a first threshold bandwidth, the switches S55 and S56 may be opened, (ii) when the radio frequency signal RF_{A} has a channel bandwidth greater than or equal to a second threshold bandwidth and less than the first threshold bandwidth, the switch S55 may be closed, and the switch S56 may be opened, and (iii) when the radio frequency signal RF_{A} has a channel bandwidth less than the second threshold bandwidth, the switch S55 may be opened, and the switch S56 may be closed. In a case where the radio frequency signal RF_{B} is to be amplified by the power amplifier 2B, (i) when the radio frequency signal RF_{B} has a channel bandwidth greater than or equal to the second threshold bandwidth, the switch S55 may be closed, and the switch S56 may be opened, and (ii) when the radio frequency signal RF_{B} has a channel bandwidth less than the second threshold bandwidth, the switch S55 may be opened, and the switch S56 may be closed. In a case where the radio frequency signal RF_{C} is to be amplified by the power amplifier 2B, the switch S55 may be closed, and the switch S56 may be opened.

The configuration mentioned above can switch between opening and closing of the switches S55 and S56 in accordance with the band and channel bandwidth of a radio frequency signal, and consequently achieve the balance between reduction of noise and reduction of degradation of the discrete voltages in the voltage supply paths P41 and P42.

For example, in the tracker circuit 1B according to the modification, Band A may be included in the range of 3300 to 5000 MHz, and Bands B and C may each be included in the range of 1427 to 2690 MHz.

The configuration mentioned above allows the filter circuit 40C to achieve, for a band that has a greater available channel bandwidth and is higher in frequency, a greater number of types of stopbands in accordance with the channel bandwidth. This configuration can more finely control the stopband in accordance with the channel bandwidth, and thus effectively reduce spurious emissions in the power amplifiers 2A and 2B.

In the circuit configuration in each of FIGS. 9 to 11, the tracker circuit 1B may further include any one or more additional filter circuits on the voltage supply path P41. For example, the tracker circuit 1B may include any additional filter circuit that is connected at one end to the output switching circuit 30 and that is connected at the other end to the filter circuit 40B/40C and the external connection terminal 141, and/or any additional filter circuit that is connected at one end to the output switching circuit 30 and the filter circuit 40B/40C and that is connected at the other end to the external connection terminal 141. For example, in FIG. 11, any additional filter circuit may be connected between the output switching circuit 30, and a node on the voltage supply path P41 to which the switch S55 of the filter circuit 40C is connected. In another example, any additional filter circuit may be connected between the node on the voltage supply path P41 to which the switch S55 of the filter circuit 40C is connected, and a node on the voltage supply path P41 to which the switch S56 of the filter circuit 40C is connected. In another example, any additional filter circuit may be connected between the node on the voltage supply path P41 to which the switch S56 is connected, and the external connection terminal 141. As with, for example, the filter circuit 40B/40C, such any additional filter circuits may include an inductor, a capacitor, and a switch.

### Exemplary Embodiment 3

The Exemplary Embodiment 3 will now be described. A tracker circuit according to the Exemplary Embodiment 3 differs from the tracker circuits according to the Exemplary Embodiments 1 and 2 mainly in that the tracker circuit is configured to supply a plurality of discrete voltages to three different power amplifiers. The tracker circuit according to the Exemplary Embodiment 3 will be described below with reference to the drawings, with focus on differences from the Exemplary Embodiments 1 and 2.

### 3.1 Circuit Configuration of Communication Device 7D

A communication device 7D according to the Exemplary Embodiment 3 will now be described with reference to FIG. 12. FIG. 12 is a circuit diagram of the communication device 7D according to the Exemplary Embodiment 3.

FIG. 12 illustrates an exemplary circuit configuration. The communication device 7D may be implemented by using any one of a wide variety of circuit implementations and circuit technologies. Therefore, the description of the communication device 7D provided below is not to be construed restrictively.

As illustrated in FIG. 12, the communication device 7D includes a tracker circuit 1D, power amplifiers 2A, 2B, and 2D, filters 3A to 3D, switches 4A to 4C, an RFIC 5, and antennas 6A, 6B, and 6D.

The tracker circuit 1D is configured to supply the power amplifiers 2A and 2B with a plurality of discrete voltages V_{T1} and a plurality of discrete voltages V_{T2}, respectively, based on a tracking mode. The tracker circuit 1D is further configured to supply the power amplifier 2D with a plurality of discrete voltages V_{T3} based on a tracking mode. As illustrated in FIG. 12, the tracker circuit 1D includes a pre-regulator circuit 10, a switched-capacitor circuit 20, an output switching circuit 30, a filter circuit 40D, a DC power supply 50, a digital control circuit 60, and external connection terminals 141 to 143.

The external connection terminal 143 is an example of a third external connection terminal. The external connection terminal 143 is connected at a location outside the tracker circuit 1D to the power amplifier 2D, and connected at a location inside the tracker circuit 1D to the output switching circuit 30 via a voltage supply path P43.

The voltage supply path P43 is an example of a third voltage supply path. The voltage supply path P43 is part of a path connecting the output switching circuit 30 and the power amplifier 2D. In this case, the voltage supply path P43 serves to connect the output switching circuit 30 and the external connection terminal 143.

The power amplifier 2D is an example of a third power amplifier. The power amplifier 2D is connected between the RFIC 5 and the filter 3D. Further, the power amplifier 2D is connected to the tracker circuit 1D. The power amplifier 2D is configured to amplify, by using the discrete voltages V_{T3} received from the tracker circuit 1D, a radio frequency signal RF_{D} (an example of a fourth radio frequency signal) of Band D received from the RFIC 5.

The filter 3D is connected between the power amplifier 2D and the antenna 6D. The filter 3D is a band pass filter with a passband that includes the transmission band of Band D.

Band D is a frequency band for communication systems built by using RAT. Band D is predefined by a standardizing body or other entities. Band D is an example of a fourth band, and is a frequency band to which FDD is applied. According to the Exemplary Embodiment 3, Band D is included in the low band group (698 to 960 MHz). However, it is noted that Band D is not limited to a frequency band included in the low band group.

The antenna 6D is configured to output a transmission signal of Band D received from the power amplifier 2D via the filter 3D. However, it is noted that the antenna 6D is not included in the communication device 7D in an alternative aspect.

### 3.2 Circuit Configuration of Filter Circuit 40D

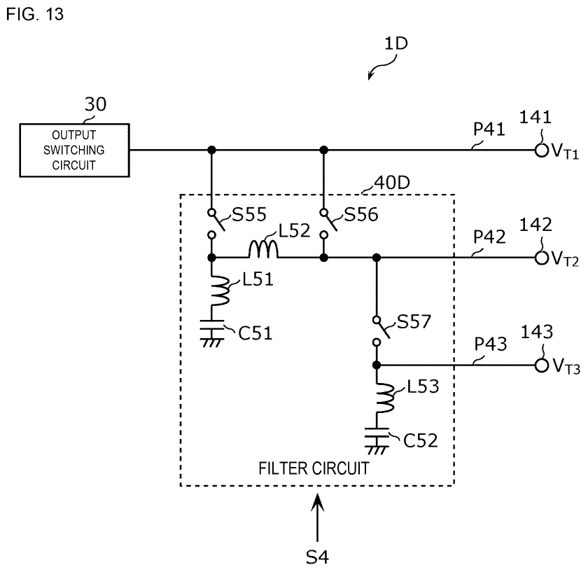

The circuit configuration of the filter circuit 40D included in the tracker circuit 1D will now be described with reference to FIG. 13. FIG. 13 is a circuit diagram of the filter circuit 40D according to the Exemplary Embodiment 3.

FIG. 13 illustrates an exemplary circuit configuration. The filter circuit 40D may be implemented by using any one of a wide variety of circuit implementations and circuit technologies. Therefore, the description of the filter circuit 40D provided below is not to be construed restrictively.

The filter circuit 40D is a pulse shaping network. The filter circuit 40D is configured to be connectable with the voltage supply paths P41 to P43. The filter circuit 40D is configured to attenuate noise components from signals (a plurality of discrete voltages) transmitted through the voltage supply paths P41 to P43. In an exemplary aspect, as illustrated in FIG. 13, the filter circuit 40D includes inductors L51 to L53, capacitors C51 and C52, and switches S55 to S57.

The inductor L53 is an example of a third inductor. The inductor L53 is connected between the voltage supply path P43 and the capacitor C52. In an exemplary aspect, one end of the inductor L53 is connected to a portion of the voltage supply path P43 that is located between the switch S57 and the external connection terminal 143. The other end of the inductor L53 is connected to the capacitor C52.

The capacitor C52 is an example of a second capacitor. The capacitor C52 is connected between the inductor L53 and ground. In an exemplary aspect, one end of the capacitor C52 is connected to the inductor L53, and the other end of the capacitor C52 is connected to ground.

The switch S57 is an example of a third switch. The switch S57 is connected between the output switching circuit 30 and the external connection terminal 143, and between the voltage supply path P42 and the inductor L53. In an exemplary aspect, one terminal of the switch S57 is connected to a portion of the voltage supply path P42 that is located between the inductor L52 and the external connection terminal 142. The other terminal of the switch S57 is connected to the inductor L53 and the external connection terminal 143.

The switch S57 connected as described above is switched between ON and OFF based on a control signal S4. In an exemplary aspect, ON/OFF of the switches S55 to S57 is controlled as described below.

(1) In a case where the radio frequency signal RF_{A} is to be amplified by the power amplifier 2A and a radio frequency signal is to be amplified by neither of the power amplifiers 2B and 2D, when the radio frequency signal RF_{A} has a channel bandwidth greater than or equal to a first threshold bandwidth, the switches S55 to S57 are opened. The inductors L51 to L53 and the capacitors C51 and C52 are thus disconnected from the voltage supply path P41. At this time, the discrete voltages V_{T1} are supplied to the power amplifier 2A via the external connection terminal 141, but the filter circuit 40D does not function as a band-reject filter with respect to the voltage supply path P41.

(2) In a case where the radio frequency signal RF_{A} is to be amplified by the power amplifier 2A and a radio frequency signal is to be amplified by neither of the power amplifiers 2B and 2D, when the radio frequency signal RF_{A} has a channel bandwidth greater than or equal to a second threshold bandwidth and less than the first threshold bandwidth, the switch S55 is closed, and the switches S56 and S57 are opened. The inductor L51 and the capacitor C51 are thus connected in shunt with the voltage supply path P41. At this time, the discrete voltages V_{T1} are supplied to the power amplifier 2A via the external connection terminal 141, and the filter circuit 40D functions as a first band-reject filter with respect to the voltage supply path P41, which is a band-reject filter with a first stopband that depends on the first threshold bandwidth.

(3) In a case where the radio frequency signal RF_{A} is to be amplified by the power amplifier 2A and a radio frequency signal is to be amplified by neither of the power amplifiers 2B and 2D, when the radio frequency signal RF_{A} has a channel bandwidth less than the second threshold bandwidth, the switch S55 is opened, and the switches S56 and S57 are closed. Thus, the inductors L52 and L51 and the capacitor C51 are connected in shunt with the voltage supply path P41 and, further, the inductor L53 and the capacitor C52 are also connected in shunt with the voltage supply path P41. At this time, the discrete voltages V_{T1} are supplied to the power amplifier 2A via the external connection terminal 141, and the filter circuit 40D functions as a second band-reject filter with respect to the voltage supply path P41, which is a band-reject filter with a second stopband that depends on the second threshold bandwidth.

(4) In a case where the radio frequency signal RF_{B} is to be amplified by the power amplifier 2B and a radio frequency signal is to be amplified by neither of the power amplifiers 2A and 2D, when the radio frequency signal RF_{B} has a channel bandwidth greater than or equal to the second threshold bandwidth, the switch S55 is closed, and the switches S56 and S57 are opened. The inductor L51 and the capacitor C51 are thus connected in shunt with the voltage supply path P42, and the inductor L52 is connected in series with the voltage supply path P42. At this time, the discrete voltages V_{T2} are supplied to the power amplifier 2B via the external connection terminal 142, and the filter circuit 40D functions as a third band-reject filter with a third stopband with respect to the voltage supply path P42.

(5) In a case where the radio frequency signal RF_{B} is to be amplified by the power amplifier 2B and a radio frequency signal is to be amplified by neither of the power amplifiers 2A and 2D, when the radio frequency signal RF_{B} has a channel bandwidth less than the second threshold bandwidth, the switch S55 is opened, and the switches S56 and S57 are closed. Thus, the inductors L52 and L51 and the capacitor C51 are connected in shunt with the voltage supply path P42 and, further, the inductor L53 and the capacitor C52 are also connected in shunt with the voltage supply path P42. At this time, the discrete voltages V_{T2} are supplied to the power amplifier 2B via the external connection terminal 142, and the filter circuit 40D functions as a second band-reject filter with a second stopband with respect to the voltage supply path P42.

(6) In a case where the radio frequency signal RF_{C} is to be amplified by the power amplifier 2B and a radio frequency signal is to be amplified by neither of the power amplifiers 2A and 2D, the switch S55 is closed, and the switches S56 and S57 are opened. Thus, the inductor L51 and the capacitor C51 are connected in shunt with the voltage supply path P42, and the inductor L52 is connected in series with the voltage supply path P42. At this time, the discrete voltages V_{T2} are supplied to the power amplifier 2B via the external connection terminal 142, and the filter circuit 40D functions as a third band-reject filter with a third stopband with respect to the voltage supply path P42.

(7) In a case where the radio frequency signal RF_{D} is to be amplified by the power amplifier 2D and a radio frequency signal is to be amplified by neither of the power amplifiers 2A and 2B, the switch S55 is opened, and the switches S56 and S57 are closed. Thus, the inductors L52 and L51 and the capacitor C51 are connected in shunt with the voltage supply path P43 and, further, the inductor L53 and the capacitor C52 are also connected in shunt with the voltage supply path P43. At this time, the discrete voltages V_{T3} are supplied to the power amplifier 2D via the external connection terminal 143, and the filter circuit 40D functions as a second band-reject filter with a second stopband with respect to the voltage supply path P43.

The first threshold bandwidth and the second threshold bandwidth to be used in the above-mentioned control of the switches S55 to S57 may be threshold bandwidths similar to those according to the modification of the Exemplary Embodiment 2.

With the above-described switch control, the filter circuit 40D functions as a variable band-reject filter with a stopband that varies with the channel bandwidth.

In the circuit configuration in each of FIGS. 12 and 13, the tracker circuit 1D may further include any one or more additional filter circuits on the voltage supply path P41. For example, the tracker circuit 1D may include any additional filter circuit that is connected at one end to the output switching circuit 30 and that is connected at the other end to the filter circuit 40D and the external connection terminal 141, and/or any additional filter circuit that is connected at one end to the output switching circuit 30 and the filter circuit 40D and that is connected at the other end to the external connection terminal 141. For example, in FIG. 13, any additional filter circuit may be connected between the output switching circuit 30, and a node on the voltage supply path P41 to which the switch S55 of the filter circuit 40D is connected. In another example, any additional filter circuit may be connected between the node on the voltage supply path P41 to which the switch S55 of the filter circuit 40D is connected, and a node on the voltage supply path P41 to which the switch S56 of the filter circuit 40D is connected. In another example, any additional filter circuit may be connected between the node on the voltage supply path P41 to which the switch S56 of the filter circuit 40D is connected, and the external connection terminal 141. As with, for example, the filter circuit 40D, such any additional filter circuits may include an inductor, a capacitor, and a switch.

### 3.3 Technical Effects

As described above, in the tracker circuit 1D according to the Exemplary Embodiment 3, the output switching circuit 30 may further be configured to selectively output at least one of the discrete voltages to the power amplifier 2D. The power amplifier 2D may be configured to amplify the radio frequency signal RF_{D} of Band D to which FDD is applied. The tracker circuit 1D may further include the voltage supply path P43 connecting the output switching circuit 30 and the power amplifier 2D. The filter circuit 40D may further include the inductor L53, the capacitor C52, and the switch S57. The inductor L53 and the capacitor C52 may be connected in shunt with the voltage supply path P42 via the switch S57, and may be connected in shunt with the voltage supply path P43. The switch S57 may be connected in series with the voltage supply path P43. One terminal of the switch S57 may be connected to a portion of the voltage supply path P42 that is located between the inductor L52 and the power amplifier 2B. The other terminal of the switch S57 may be connected to the power amplifier 2D.

That is, the tracker circuit 1D according to the Exemplary Embodiment 3 may further include: the external connection terminal 143 connected to the power amplifier 2D, the power amplifier 2D being configured to amplify the radio frequency signal RF_{D} of Band D to which FDD is applied; and the voltage supply path P43 connecting the output switching circuit 30 and the external connection terminal 143. The filter circuit 40D may further include the inductor L53, the capacitor C52, and the switch S57. The inductor L53 and the capacitor C52 may be connected between the voltage supply path P42 and ground via the switch S57, and may be connected between the voltage supply path P43 and ground. The switch S57 may be connected between the output switching circuit 30 and the external connection terminal 143. One terminal of the switch S57 may be connected to a portion of the voltage supply path P42 that is located between the inductor L52 and the external connection terminal 142. The other terminal of the switch S57 may be connected to the external connection terminal 143.

According to the configuration mentioned above, the switches S55 to S57 enable switching of connections of a subset or all of the inductors L51 to L53 and the capacitors C51 and C52 to the voltage supply paths P41 to P43. This allows the stopband of the filter circuit 40D to be varied. In particular, as for the voltage supply path P41, the three switches S55 to S57 enable switching between the following states: disconnecting the inductors L51 to L53 and the capacitors C51 and C52 from the voltage supply path P41; connecting, in shunt with the voltage supply path P41, the inductor L51 and the capacitor C51; and connecting, in shunt with the voltage supply path P41, the inductors L51 to L53 and the capacitors C51 and C52. As for the voltage supply path P42, the three switches S55 to S57 enable switching between the following states: connecting, in shunt with the voltage supply path P42, the inductor L51 and the capacitor C51, and connecting the inductor L52 in series with the voltage supply path P42; and connecting, in shunt with the voltage supply path P42, the inductors L51 to L53 and the capacitors C51 and C52. In this way, for the filter circuit 40D, the three switches S55 to S57 can achieve switching between a plurality of stopbands with respect to the three voltage supply paths P41 to P43.

For example, in the tracker circuit 1D according to the Exemplary Embodiment 3, in a case where the radio frequency signal RF_{A} is to be amplified by the power amplifier 2A, (i) when the radio frequency signal RF_{A} has a channel bandwidth greater than or equal to a first threshold bandwidth, the switches S55, S56, and S57 may be opened, (ii) when the radio frequency signal RF_{A} has a channel bandwidth greater than or equal to a second threshold bandwidth and less than the first threshold bandwidth, the switch S55 may be closed, and the switches S56 and S57 may be opened, and (iii) when the radio frequency signal RF_{A} has a channel bandwidth less than the second threshold bandwidth, the switch S55 may be opened, and the switches S56 and S57 may be closed. In a case where the radio frequency signal RF_{B} is to be amplified by the power amplifier 2B, (i) when the radio frequency signal RF_{B} has a channel bandwidth greater than or equal to the second threshold bandwidth, the switch S55 may be closed, and the switches S56 and S57 may be opened, and (ii) when the radio frequency signal RF_{B} has a channel bandwidth less than the second threshold bandwidth, the switch S55 may be opened, and the switches S56 and S57 may be closed. In a case where the radio frequency signal RF_{C} is to be amplified by the power amplifier 2B, the switch S55 may be closed, and the switches S56 and S57 may be opened. In a case where the radio frequency signal RF_{D} is to be amplified by the power amplifier 2D, the switch S55 may be opened, and the switches S56 and S57 may be closed.

The configuration mentioned above makes can switch between opening and closing of the switches S55 to S57 in accordance with the band and channel bandwidth of a radio frequency signal, and consequently achieve the balance between reduction of noise and reduction of degradation of the discrete voltages in the voltage supply paths P41 to P43.

For example, in the tracker circuit 1D according to the Exemplary Embodiment 3, Band A may be included in the range of 3300 to 5000 MHz, Bands B and C may each be included in the range of 1427 to 2690 MHz, and Band D may be included in the range of 698 to 960 MHz.

The configuration mentioned above allows the filter circuit 40D to achieve, for a band that has a greater available channel bandwidth and is higher in frequency, a greater number of types of stopbands in accordance with the channel bandwidth. This can more finely control the stopband in accordance with the channel bandwidth, and thus effectively reduce spurious emissions in the power amplifiers 2A, 2B, and 2D.

### Other the Exemplary Embodiments

Although the tracker circuit, the tracker module, and the tracking method according to the present disclosure have been described above based on the exemplary embodiments thereof, the tracker circuit, the tracker module, and the tracking method according to the present disclosure are not limited to the exemplary embodiments mentioned above. The exemplary aspects of the present disclosure are intended to also encompass: other embodiments implemented by combining any constituent elements in the above embodiments; modifications obtained by modifying the above exemplary embodiments in various ways as may become apparent to those skilled in the art without departing from the scope of the present disclosure; and various devices incorporating the tracker circuit mentioned above.

For example, in the circuit configurations of the various circuits according to the above exemplary embodiments, another circuit element, wiring line, and other features may be inserted between individual circuit elements and paths connecting signal paths disclosed in the drawings. For example, an impedance matching circuit may be inserted between the power amplifier 2A and the filter 3A.

According to the above exemplary embodiments, a plurality of discrete voltages are supplied from the switched-capacitor circuit to the output switching circuit. This configuration, however, is not intended to be limiting. For example, a plurality of voltages may each be supplied from a corresponding one of a plurality of DC-DC converters. If the levels of the discrete voltages are at equal intervals, use of a switched-capacitor circuit can be used, and effective in reducing the size of the tracker module.

According to the above exemplary embodiments, four discrete voltages are supplied to a power amplifier. The number of discrete voltages, however, is not limited to four. For example, improved PAE can be achieved as long as a plurality of discrete voltages include at least the following voltages: a voltage corresponding to the maximum output power; and a voltage corresponding to the output power with the highest frequency of occurrence.

According to the Exemplary Embodiment 1 described above, the circuit components of the tracker circuit 1A are disposed on the major face 90a of the module laminate 90. Alternatively, the circuit components may be disposed on both the major faces 90a and 90b. In this case, for example, the integrated circuit 80 may be disposed on the major face 90b.

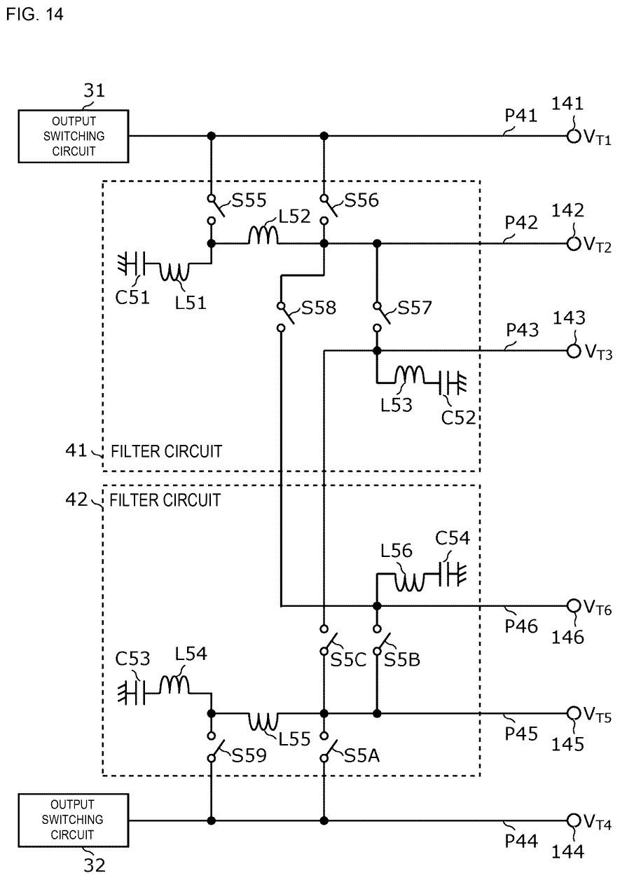

According to the above exemplary embodiments, the tracker circuit includes a single output switching circuit 30. Alternatively, the tracker circuit may include a plurality of output switching circuits. For example, as illustrated in FIG. 14, the tracker circuit may include two output switching circuits, and may be configured to supply a plurality of discrete voltages to six power amplifiers via six external connection terminals.

FIG. 14 is a circuit diagram of filter circuits 41 and 42 according to another exemplary embodiment. In FIG. 14, the tracker circuit includes two output switching circuits 31 and 32, two filter circuits 41 and 42, and six external connection terminals 141 to 146.

The external connection terminals 144 to 146 are each connected to a different power amplifier (not illustrated). The external connection terminals 144 to 146 are terminals for supplying a plurality of discrete voltages V_{T4} to V_{T6}, respectively.

The output switching circuits 31 and 32 each have a configuration similar to that of the output switching circuit 30, and thus a detailed description thereof is omitted.

The filter circuits 41 and 42 each have a configuration similar to that of the filter circuit 40D. In an exemplary aspect, the filter circuit 41 includes inductors L51 to L53, capacitors C51 and C52, and switches S55 to S58. The switch S58 is connected between the voltage supply path P42 and the external connection terminal 146. Closing of the switch S58 allows the output switching circuit 31 to output a plurality of discrete voltages to the external connection terminal 146.

In the filter circuit 42, inductors L54 to L56, capacitors C53 and C54, switches S59 to S5C, and voltage supply paths P44 to P46 correspond to the inductors L51 to L53, the capacitors C51 and C52, the switches S55 to S58, and the voltage supply paths P41 to P43, respectively.

The exemplary aspects of the present disclosure can be used for a wide variety of communication devices such as mobile phones, as a tracker circuit that supplies voltage to a power amplifier.

### REFERENCE SIGNS LIST

1A, 1, 1D tracker circuit
2A, 2B, 2D power amplifier
3A, 3B, 3C, 3D filter
4A, 4B, 4C switch
5 RFIC
6A, 6B, 6D antenna
7A, 7B, 7D communication device
10 pre-regulator circuit
20 switched-capacitor circuit
30, 31, 32 output switching circuit
40A, 40B, 40C, 40D, 41, 42 filter circuit
50 DC power supply
60 digital control circuit
61 first controller
62 second controller
80 integrated circuit
80a PR switch portion
80b SC switch portion
80c OS switch portion
80d filter switch portion
90 module laminate
90a, 90b major face
90e ground plane
91 resin member
92 shield electrode layer
100 tracker module
110, 131, 132, 133, 134 input terminal
111, 112, 113, 114, 130 output terminal
115, 116 inductor connection terminal
141, 142, 143, 144, 145, 146 external connection terminal
150 electrode
601, 602, 603, 604 control terminal
P41, P42, P43, P44, P45, P46 voltage supply path

What is claimed is:

1. A tracker circuit comprising:
an output switching circuit configured to selectively output at least one of a plurality of discrete voltages;
a first voltage supply path configured to connect the output switching circuit and a first power amplifier to provide the at least one of the plurality of discrete voltages to the first power amplifier; and
a filter circuit configured to be connected in shunt with the first voltage supply path,
wherein the first power amplifier is configured to amplify a first radio frequency signal of a first band with time division duplex being applied thereto.

2. The tracker circuit according to claim 1, wherein the filter circuit includes a first inductor, a first capacitor, and a first switch that are connected in series, and in shunt with the first voltage supply path.

3. The tracker circuit according to claim 2, wherein:
when the first radio frequency signal has a channel bandwidth greater than or equal to a first threshold bandwidth, the first switch is configured to be opened to disconnect the filter circuit to the first voltage supply path; and
when the first radio frequency signal has a channel bandwidth less than the first threshold bandwidth, the first switch is configured to be closed to connect the filter circuit to the first voltage supply path.

4. The tracker circuit according to claim 3, wherein the filter circuit is configured to have a stopband based on the first threshold bandwidth.

5. The tracker circuit according to claim 1, wherein the first band is in a range of 3300 to 5000 MHz.

6. The tracker circuit according to claim 2, further comprising:
a second voltage supply path configured to provide the at least one of the plurality of discrete voltages to a second power amplifier,
wherein the second power amplifier is configured to amplify at least one of a second radio frequency signal or a third radio frequency signal, the second radio frequency signal being of a second band with time division duplex being applied thereto, the third radio frequency signal being of a third band with frequency division duplex being applied thereto;
wherein the first inductor and the first capacitor are connected in shunt with the second voltage supply path, and the first switch is configured to connect or disconnect at least one of the filter circuit and the second voltage supply path to the first voltage supply path.

7. The tracker circuit according to claim 6, wherein:
for amplifying the first radio frequency signal by the first power amplifier,
(i) when the first radio frequency signal has a channel bandwidth greater than or equal to a first threshold bandwidth, the first switch is configured to be opened to disconnect the filter circuit to the first voltage supply path, and
(ii) when the first radio frequency signal has a channel bandwidth less than the first threshold bandwidth, the first switch is configured to be closed to connect the filter circuit to the first voltage supply path, and
wherein, for amplifying the second radio frequency signal or the third radio frequency signal by the second power amplifier, the first switch is configured to be closed.

8. The tracker circuit according to claim 6, wherein the filter circuit further includes:
a second switch configured to connect or disconnect the first voltage supply path with the second voltage supply path; and
a second inductor configured to be connected or disconnected with the first inductor and the first capacitor based on the first switch and the second switch.

9. The tracker circuit according to claim 8, wherein:
for amplifying the first radio frequency signal by the first power amplifier,
(i) when the first radio frequency signal has a channel bandwidth greater than or equal to a first threshold bandwidth, the first switch and the second switch are configured to be opened,
(ii) when the first radio frequency signal has a channel bandwidth greater than or equal to a second threshold bandwidth and less than the first threshold bandwidth, the first switch is configured to be closed, and the second switch is configured to be opened, and
(iii) when the first radio frequency signal has a channel bandwidth less than the second threshold bandwidth, the first switch is configured to be opened, and the second switch is configured to be closed,
wherein, for amplifying the second radio frequency signal by the second power amplifier,
(i) when the second radio frequency signal has a channel bandwidth greater than or equal to the second threshold bandwidth, the first switch is configured to be closed, and the second switch is configured to be opened, and
(ii) when the second radio frequency signal has a channel bandwidth less than the second threshold bandwidth, the first switch is configured to be opened, and the second switch is configured to be closed, and
wherein, for amplifying the third radio frequency signal by the second power amplifier, the first switch is configured to be closed, and the second switch is configured to be opened.

10. The tracker circuit according to claim 6, wherein:
the first band is in a range of 3300 to 5000 MHz; and
the second band and the third band are each in a range of 1427 to 2690 MHz.

11. The tracker circuit according to claim 8, further comprising:
a third voltage supply path configured to provide the at least one of the plurality of discrete voltages to a third power amplifier;
wherein the third power amplifier is configured to amplify a fourth radio frequency signal of a fourth band with frequency division duplex being applied;
wherein:
the filter circuit further includes a third inductor, a second capacitor, and a third switch;
the third inductor and the second capacitor are configured to be connected in shunt with the second voltage supply path via the third switch, and to be connected in shunt with the third voltage supply path; and
the third switch is configured to connect or disconnect the second voltage supply path with the third voltage supply path.

12. The tracker circuit according to claim 11, wherein:
for amplifying the first radio frequency signal by the first power amplifier,
(i) when the first radio frequency signal has a channel bandwidth greater than or equal to a first threshold bandwidth, the first switch, the second switch, and the third switch are configured to be opened,
(ii) when the first radio frequency signal has a channel bandwidth greater than or equal to a second threshold bandwidth and less than the first threshold bandwidth, the first switch is configured to be closed, and the second switch and the third switch are configured to be opened, and
(iii) when the first radio frequency signal has a channel bandwidth less than the second threshold bandwidth, the first switch is configured to be opened, and the second switch and the third switch are configured to be closed,
wherein, for amplifying the second radio frequency signal by the second power amplifier,
(i) when the second radio frequency signal has a channel bandwidth greater than or equal to the second threshold bandwidth, the first switch is configured to be closed, and the second switch and the third switch are configured to be opened, and
(ii) when the second radio frequency signal has a channel bandwidth less than the second threshold bandwidth, the first switch is configured to be opened, and the second switch and the third switch are configured to be closed,
wherein, for amplifying the third radio frequency signal by the second power amplifier, the first switch is configured to be closed, and the second switch and the third switch are configured to be opened, and
wherein, for amplifying the fourth radio frequency signal by the third power amplifier, the first switch is configured to be opened, and the second switch and the third switch are configured to be closed.

13. The tracker circuit according to claim 11, wherein:
the first band is included in a range of 3300 to 5000 MHz,
the second band and the third band are each included in a range of 1427 to 2690 MHz, and
the fourth band is included in a range of 698 to 960 MHz.

14. A tracker circuit comprising:
a first external connection terminal configured to be connected to a first power amplifier, the first power amplifier being configured to amplify a first radio frequency signal of a first band with time division duplex being applied;
an output switching circuit configured to selectively output at least one of a plurality of discrete voltages to the first external connection terminal;
a first voltage supply path configured to connect the output switching circuit to the first external connection terminal; and
a filter circuit configured to be connected between the first voltage supply path and a ground.

15. The tracker circuit according to claim 14, wherein:
the filter circuit includes a first inductor, a first capacitor, and a first switch that are connected in series, and
the first switch is configured to connect or disconnect the first voltage supply path with the filter circuit.

16. The tracker circuit according to claim 15, further comprising:
a second external connection terminal configured to be connected to a second power amplifier, the second power amplifier being configured to amplify at least one of a second radio frequency signal or a third radio frequency signal, the second radio frequency signal being of a second band with time division duplex being applied, the third radio frequency signal being of a third band with frequency division duplex being applied; and
a second voltage supply path configured to connect the output switching circuit with the second external connection terminal,
wherein:
the first inductor and the first capacitor are configured to be connected between the second voltage supply path and the ground; and
the first switch is configured to connect or disconnect at least one of the filter circuit and the second voltage supply path to the first voltage supply path.

17. The tracker circuit according to claim 16, wherein the filter circuit further includes:
a second switch configured to connect or disconnect the first voltage supply path to the second voltage supply path, and
a second inductor configured to be connected or disconnected with the first inductor and the first capacitor based on the first switch and the second switch.

18. The tracker circuit according to claim 17, further comprising:
a third external connection terminal configured to be connected to a third power amplifier, the third power amplifier being configured to amplify a fourth radio frequency signal of a fourth band with frequency division duplex being applied; and
a third voltage supply path configured to connect the output switching circuit to the third external connection terminal,
wherein:
the filter circuit further includes a third inductor, a second capacitor, and a third switch,
the third inductor and the second capacitor are connected between the third voltage supply path and the ground, and
the third switch is configured to connect or disconnect the second voltage supply path to the third voltage supply path.

19. A tracking method comprising:
when a radio frequency signal with time division duplex being applied has a channel bandwidth greater than or equal to a threshold bandwidth, disconnecting a filter circuit to a voltage supply path of a power amplifier to be used to amplify the radio frequence signal;
when the channel bandwidth is less than the threshold bandwidth, connecting the filter circuit to the voltage supply path; and
selectively supplying at least one of a plurality of discrete voltages to the power amplifier via the voltage supply path.

20. The tracking method according to claim 19, further comprising generating a control signal for controlling a switch in the filter circuit to be turned on or to be turned off based on the channel bandwidth.
